(19) United States
(12) Patent Application Publication
(10) Pub. No.: US 2025/0081780 A1
(43) Pub. Date: Mar. 6, 2025

(54) CONDUCTIVE PAD, DISPLAY DEVICE HAVING THE SAME AND METHOD OF PROVIDING THE SAME

(71) Applicant: Samsung Display Co., Ltd., Yongin-si, Gyeonggi-do, (KR)

(72) Inventors: CHOLONG WON, Yongin-si (KR); KIYONG KIM, Yongin-si (KR); HEEJU WOO, Yongin-si (KR); HYUNGBIN CHO, Yongin-si (KR)

(21) Appl. No.: 18/811,913

(22) Filed: Aug. 22, 2024

(30) Foreign Application Priority Data
Aug. 28, 2023 (KR) 10-2023-0113040

(51) Int. Cl. H10K 59/131; H10K 59/12; H10K 59/127; H10K 71/60

(52) U.S. Cl. CPC H10K 59/131; H10K 59/1201; H10K 59/1275; H10K 71/60

(57) ABSTRACT

A display device includes a display panel including a display region in which a light emitting element and a signal line are disposed, and a non-display region which is adjacent to the display region and in which a pad connected to the signal line is disposed. The pad includes a first conductive pattern at which the pad is connected to the signal line, an insulating pattern which is on the first conductive pattern and defines protrusions adjacent to each other in a direction along the first conductive pattern, a second conductive pattern on the insulating pattern and electrically connected to the first conductive pattern, and a conductive member between the protrusions and at least partially in the second conductive pattern.

This application claims priority to Korean Patent Application No. 10-2023-0113040 filed on Aug. 28, 2023, and all the benefits accruing therefrom under 35 U.S.C. § 119, the disclosures of which are incorporated by reference herein in their entireties.

### BACKGROUND

### (1) Field

Embodiments of the present disclosure described herein relate to a display device and a method for providing (or manufacturing) the same. More particularly, embodiments relate to a display device including a pad improved in bonding reliability and a method for providing (or manufacturing) the same.

### (2) Description of the Related Art

A display device includes a display region activated in response to an electrical signal. The display device may sense an input applied from outside of the display device through a display region while displaying various images at the display region to be provided for a user.

The display device includes a display panel and a circuit board. The display panel may be connected to a main board through the circuit board. A driving circuit chip may be mounted on the display panel.

### SUMMARY

Embodiments of the present disclosure provide a display device improved in bonding reliability and a method for providing (or manufacturing) the same.

According to an embodiment of the present disclosure, a display device includes a display panel including a display region and a non-display region adjacent to the display region, insulating layers disposed on the base layer, a light emitting element disposed in the display region, a pad disposed in the non-display region, and a signal line connected to the pad. The pad includes a first conductive pattern connected to the signal line and disposed on the insulating layers, an insulating pattern including protrusions protruding in a direction away from the first conductive pattern and disposed on the first conductive pattern, a second conductive pattern disposed on the insulating pattern, and a conductive member interposed between the protrusions. At least a portion of the conductive member may be inserted into the second conductive pattern, such that the conductive member is at least partially in the second conductive pattern.

The insulating pattern may have a continuous integral form, the protrusions may include a first protrusion and a second protrusion connected to the first protrusion, and a valley may be defined between the first protrusion and the second protrusion.

The width of each of the protrusions in a direction which the protrusions are arranged may be decreased in the direction away from the first conductive pattern.

At least a portion of the conductive member may be inserted into the insulating pattern.

The second conductive pattern may include a (2-1)-th pattern layer, a (2-2)-th pattern layer disposed on the (2-1)-th pattern layer, and a (2-3)-th pattern layer disposed on the (2-2)-th pattern layer. The (2-1)-th pattern layer and (2-3)-th pattern layer may include titanium (Ti), and the (2-2)-th pattern layer may include aluminum (Al).

The thickness of the (2-3)-th pattern layer may be smaller than the thickness of the (2-2)-th pattern layer, and the portion of the conductive member inserted into the second conductive pattern may is exposed from a portion of the (2-3)-th pattern layer by passing through the (2-3)-th pattern layer.

The second conductive pattern may include a (2-1)-th pattern layer and a (2-2)-th pattern layer disposed on the (2-1)-th pattern layer. The (2-1)-th pattern layer may include copper (Cu) and the (2-2)-th pattern layer may include indium tin oxide (ITO).

The first conductive pattern may include a top surface on which the insulating pattern is disposed, a bottom surface opposite to the top surface, and a side surface connected to the top surface and the bottom surface. The second conductive pattern may make contact with a portion of the top surface and the side surface, which are exposed from the insulating pattern.

A driving chip disposed in the non-display region and a bump overlapped with the pad may be further included. The bump and the second conductive pattern may at least partially make contact with each other.

At least a portion of the conductive member protruding from the second conductive pattern may make contact with the bump.

The conductive member may include conductive particles, and the conductive particles may be randomly arranged in the second conductive pattern.

The conductive member may include spherical conductive particles having an uneven outer surface.

The conductive member may include a metal paste, and at least a portion of the metal paste may be inserted into the first conductive pattern.

The insulating pattern may include a polymer.

Each of the protrusions may include a first side surface facing an adjacent protrusion when viewed in a cross-sectional view, and a second side surface facing the first side surface. The conductive member may be interposed between the first side surfaces, and the pad may further include an additional conductive member disposed on at least one of the second side surfaces.

The protrusions may include a first protrusion, a second protrusion connected to the first protrusion, and a third protrusion connected to the second protrusion and spaced apart from the first protrusion while interposing the second protrusion between the first protrusion and the third protrusion. The insulating pattern may include a valley defined between the first protrusion and the second protrusion, and between the second protrusion and the third protrusion.

A metal layer disposed on the second conductive pattern may be further included, and the metal layer may cover the second conductive pattern.

According to an embodiment of the present disclosure, a method for manufacturing (or providing) a display device may include providing a preliminary display device including a base layer including a display region and a non-display region adjacent to the display region and insulating layers disposed on the base layer, forming (or providing) a first conductive pattern in the non-display region of the base layer, forming a preliminary insulating pattern on the first conductive pattern, forming an insulating pattern including a protrusion protruding in a direction away from the first conductive pattern, forming a conductive member between protrusions, and forming a second conductive pattern on the insulating pattern.

At least a portion of the conductive member may be inserted into the second conductive pattern.

The forming of the conductive member may include disposing a discharging member above the insulating pattern, and discharging the conductive member from the discharging member.

The method may further include disposing a bump on the second conductive pattern and pressing the second conductive pattern by moving the bump toward the second conductive pattern.

In the pressing of the second conductive pattern, the portion of the conductive member inserted into the second conductive pattern may be at least partially exposed from the second conductive pattern.

The method may further include forming a metal layer on the second conductive pattern after forming the second conductive pattern.

### BRIEF DESCRIPTION OF THE FIGURES

The above and other objects and features of the present disclosure will become apparent by describing in detail embodiments thereof with reference to the accompanying drawings.

FIG. 1 is a perspective view of an electronic device according to an embodiment of the present disclosure.

FIG. 2 is an exploded perspective view of an electronic device according to an embodiment of the present disclosure.

FIG. 3 is a cross-sectional view of a display device according to an embodiment of the present disclosure.

FIG. 4 is a plan view of a display panel according to an embodiment of the present disclosure.

FIG. 5 is a cross-sectional view of a display panel according to an embodiment of the present disclosure.

FIG. 6A is a cross-sectional view of an input sensing unit according to an embodiment of the present disclosure.

FIG. 6B is a plan view of an input sensing unit according to an embodiment of the present disclosure.

FIG. 6C is a cross-sectional view of a portion of a display device taken along line I-I′ of FIG. 6B.

FIG. 7 is an exploded perspective view of pad region of a display device according to an embodiment of the present disclosure.

FIG. 8 is a cross-sectional view of a portion of a display device taken along line II-II′ of FIG. 7.

FIGS. 9A to 9H are cross-sectional views sequentially illustrating structures and processes in a method for providing (or manufacturing) a display device according to an embodiment of the present disclosure.

FIG. 9I is an enlarged view of region AA′ of FIG. 9H.

FIG. 9J is a cross-sectional view of a conductive member according to an embodiment of the present disclosure.

FIG. 10A is a cross-sectional view of a portion of a display device according to an embodiment of the present disclosure.

FIG. 10B is a cross-sectional view of a portion of a display device according to an embodiment of the present disclosure.

FIG. 10C is a cross-sectional view of a portion of a display device according to an embodiment of the present disclosure.

FIG. 10D is a cross-sectional view of a portion of a display device according to an embodiment of the present disclosure.

### DETAILED DESCRIPTION

While the present disclosure is susceptible to various modifications and alternative forms, embodiments thereof are shown by way of example in the drawings and will be described herein in detail. It should be understood, however, that there is no intent to limit the present disclosure to the particular forms disclosed, but on the contrary, the present disclosure is to cover all modifications, equivalents, and alternatives falling within the spirit and scope of the present disclosure.

In the specification, the expression that a first component (or region, layer, part, portion, etc.) is related to another element such as being “on”, “connected to”, or “coupled to” a second component means that the first component is directly on, connected to, or coupled to the second component or means that a third component is interposed therebetween. In contrast, the expression that a first component (or region, layer, part, portion, etc.) is related to another element such as being “directly on”, “directly connected to”, or “directly coupled to” a second component means that no third component is interposed therebetween.

The same or similar reference numerals will be assigned to the same component. Within the Figures and the text of the disclosure, a reference number indicating a singular form of an element may also be used to reference to a plurality of the singular element. In addition, in drawings, thicknesses, proportions, and dimensions of components may be exaggerated to describe the technical features effectively.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” The term “and/or” includes any and all combinations of one or more of associated components

Although the terms “first”, “second”, etc. may be used to describe various components, the components should not be construed as being limited by the terms. The terms are only used to distinguish one component from another component. For example, without departing from the scope and spirit of the present disclosure, a first component may be referred to as a second component, and similarly, the second component may be referred to as the first component.

The singular forms are intended to include the plural forms unless the context clearly indicates otherwise.

In addition, the terms “under”, “at a lower portion”, “above”, “an upper portion” are used to describe the relationship between components illustrated in drawings. The terms are relative and are described with reference to a direction indicated in the drawing.

It will be further understood that the terms “comprises,” “comprising,” “includes,” or “including,” or “having” specify the presence of stated features, numbers, steps, operations, components, parts, or the combination thereof, but do not preclude the presence or addition of one or more other features, numbers, steps, operations, components, components, and/or the combination thereof.

Unless otherwise defined, all terms (including technical terms and scientific terms) used in the specification have the same meaning as those commonly understood by one skilled in the art to which the present disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described with reference to accompanying drawings.

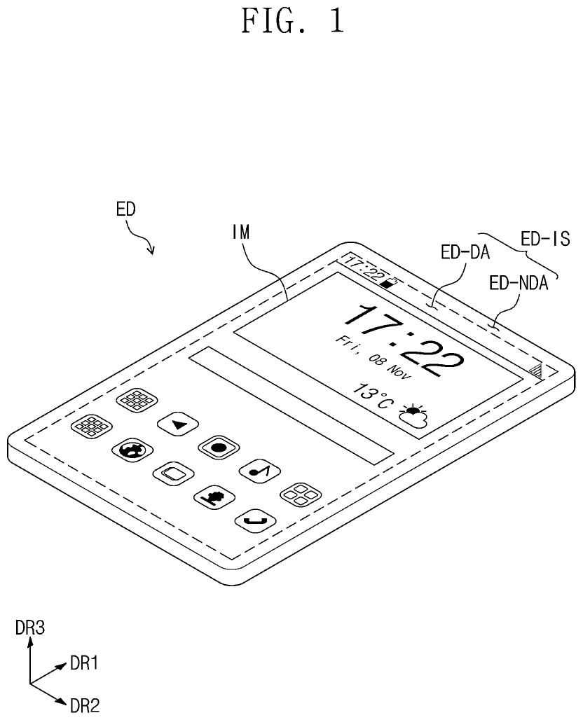

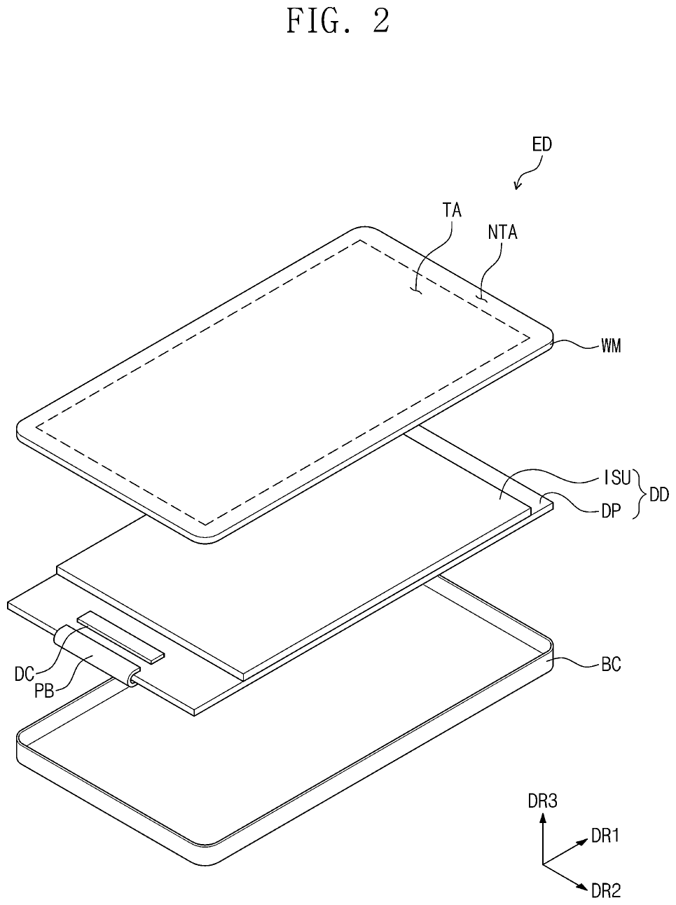

FIG. 1 is a perspective view of an electronic device ED according to an embodiment of the present disclosure. FIG. 2 is an exploded perspective view of an electronic device ED according to an embodiment of the present disclosure.

An electronic device ED may be activated in response to an electrical signal. According to an embodiment, the electronic device ED is provided in the form of a smartphone by way of example. However, the present disclosure is not limited thereto, and the electronic device ED according to an embodiment may have various forms. For example, the electronic device ED may be applied to a personal computer, a laptop computer, a television, a personal digital terminal, a car navigation system, a game console, a smartphone, a tablet, or a camera.

The electronic device ED may display an image IM through a display plane ED-IS as a display surface. FIG. 1 illustrates icon images as an example of the image IM. The display plane ED-IS is parallel to a plane defined by a first direction DR1 and a second direction DR2 crossing each other.

FIG. 1 and drawings thereafter illustrate the first direction DR1 to a third direction DR3, and directions indicated by the first direction DR1 to the third direction DR3 described in this specification may be relative concepts and may be converted into other directions.

For the convenience of explanation in this specification, the third direction DR3 is defined as a direction in which an image IM is provided, such as to outside the electronic device ED and/or for a user thereof. In addition, the first direction DR1 and the second direction DR2 may be perpendicular to each other. The third direction DR3 may be a direction normal to the plane defined by the first direction DR1 and the second direction DR2. A thickness of the electronic device ED and various components or layers thereof may be defined along the third direction DR3 (e.g., a thickness direction).

The display plane ED-IS includes a display region ED-DA to display the image IM and a non-display region ED-NDA which is adjacent to the display region ED-DA. The non-display region ED-NDA may be a region (or planar area) in which the image IM is not displayed. However, the present disclosure is not limited thereto. The non-display region ED-NDA may be adjacent to any one side of the display region ED-DA or may be omitted.

Referring to FIG. 2, according to an embodiment, the electronic device ED may include a window WM, a display device DD, and a receiving member BC.

The window WM may be disposed on or facing the display device DD, and may transmit an image IM provided from the display device DD to the outside (e.g., outside of the window WM, outside of the electronic device ED, etc.). The window WM may include a transmission region TA and a non-transmission region NTA.

The transmission region TA may be overlapped with the display region ED-DA illustrated in FIG. 1 and may have a form (or planar shape) corresponding to the display region ED-DA. The transmission region TA may a region in which the image IM (see FIG. 1) provided from the display device DD is transmitted to the outside.

The non-transmission region NTA may be overlapped with the non-display region ED-NDA illustrated in FIG. 1 and may have a form corresponding to the non-display region ED-NDA. The non-transmission region NTA has a light transmittance lower than a light transmittance of the transmission region TA. The non-transmission region NTA may be defined by a bezel pattern provided in a partial region of the base layer of the window WM. The region, in which the bezel pattern is not disposed (e.g., excluded or absent), is defined as the transmission region TA. However, the present disclosure is not limited thereto, and the non-transmission region NTA may be omitted such that the transmission region TA extends to an outer edge of the electronic device ED in the plan view.

Although not illustrated, the window WM may include a base layer and functional layers which are disposed on the base layer. The functional layers may include a protective layer and an anti-fingerprint layer. The base layer of the window WM may include glass, sapphire, or plastic. The base layer of the window WM may include an optically transparent material. For example, the base layer of the window WM may include a glass or plastic film or may include a glass substrate and a plastic film coupled to each other by an adhesive.

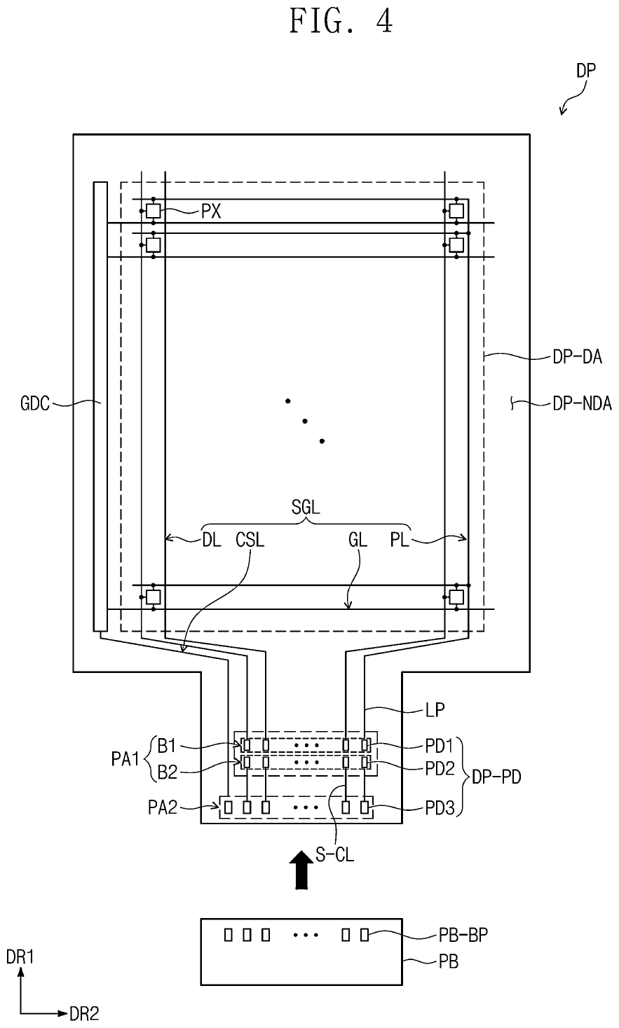

Although not illustrated, an anti-reflective layer may be disposed between the window WM and the display device DD. The anti-reflective layer may reduce reflectance of external light incident from the outside of the display device DD. The anti-reflective layer may include color filters. The color filters may have a specific array. For example, the color filters may be arranged based on light emitting colors of pixels PX (see FIG. 4) included in a display panel DP to be described below. In addition, the anti-reflective layer may further include a black matrix adjacent to the color filters.

Referring to FIG. 2, the display device DD according to an embodiment may include the display panel DP and an input sensing unit ISU.

The display panel DP may be a liquid crystal display panel or an emissive-display panel. For example, the display panel DP may include a liquid crystal display panel including a liquid crystal element, an organic electroluminescent display panel including an organic electroluminescent element, or a quantum dot light emitting display panel including a quantum dot light emitting element. However, the embodiment is not limited thereto. Hereinafter, the display panel DP may be described as an organic light emitting display panel.

The input sensing unit ISU as an input sensing layer may be disposed on the display panel DP. The input sensing unit ISU may include any one of a capacitive sensor, an optical sensor, an ultrasonic sensor, an electromagnetic induction sensor. The input sensing unit ISU may be formed on (or provided on) the display panel DP through a subsequent process in a method of providing the electronic device ED. Alternatively, the input sensing unit ISU may be fabricated separately and may be bonded onto the display panel DP through an adhesive layer.

The display device DD may further include a driving chip DC and a circuit board PB which are disposed on the display panel DP.

According to an embodiment, the circuit board PB may be a flexible circuit board. In the following description, although the circuit board PB is described as the flexible circuit board and the same reference numeral is assigned to the circuit board, the present disclosure is not limited thereto. For example, the circuit board PB may be rigid. The flexible circuit board PB may electrically connect the display panel DP to a main circuit board (not shown) as a component external to the display panel DP.

Although FIG. 2 illustrates that the driving chip DC is mounted on the display panel DP, the present disclosure is not limited thereto. For example, the driving chip DC may be mounted on the flexible circuit board PB. The driving chip DC may include a driving element, such as a data driving circuit, to drive a pixel PX of the display panel DP. According to an embodiment, the driving chip DC and the flexible circuit board PB directly mounted on the display panel DP may be collectively referred to as an electronic part. Hereinafter, the bonding structure between the display panel DP and the flexible circuit board PB may be identically applied to another electronic part other than the flexible circuit board PB such as the driving chip DC.

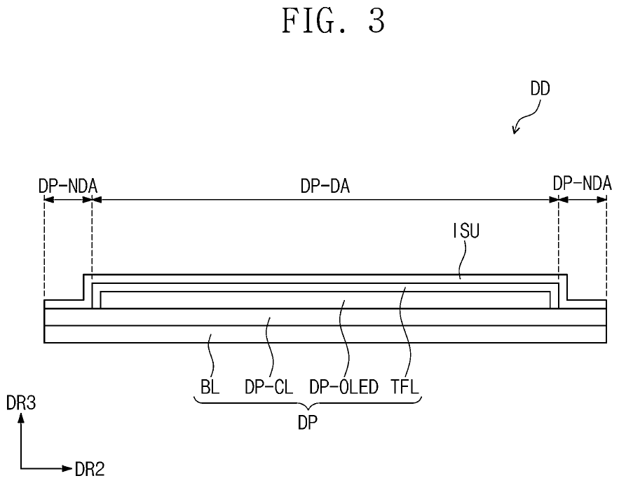

FIG. 2 illustrates that the circuit board PB is bendable to be bent and disposed on a rear surface of the display panel DP. However, the present disclosure is not limited thereto. For example, a portion of the display panel DP may be bendable to be bent such that the driving chip DC faces a lower portion of the display device DD. In this case, the display panel DP may be bent in a non-display region DP-NDA (see FIG. 3). The circuit board PB may be disposed at one end portion of a base layer BL of the display panel DP (see FIG. 3), and may be connected to a circuit element layer DP-CL at the one end portion of the display panel DP (see FIG. 3).

The receiving member BC may receive the display device DD and may be coupled to the window WM. The flexible circuit board PB may be disposed at one end portion of the display panel DP, and may be electrically connected to the display panel DP, at the circuit element layer DP-CL to be described with reference to FIG. 3. Although not illustrated, the display device DD may further include a main board, electronic modules, a camera module, or a power module which is mounted on the main board.

Although the above description has been made regarding the electronic device ED in the form of the cellular phone, the electronic device ED may include a device formed by bonding at least two electronic parts to each other. For example, the electronic device ED may represent the display panel DP and the driving chip DC which is mounted on the display panel DP.

FIG. 3 is a cross-sectional view of a display device DD according to an embodiment of the present disclosure.

The display panel DP includes the base layer BL, the circuit element layer DP-CL disposed on the base layer BL, a display element layer DP-OLED disposed on the circuit element layer DP-CL, and an encapsulating layer TFL disposed on the display element layer DP-OLED.

The display panel DP may include a display region DP-DA and the non-display region DP-NDA. The display region DP-DA of the display panel DP may correspond to the display region ED-DA of the electronic device ED described with reference to FIG. 1 and the transmission region TA described with reference to FIG. 2. The non-display region DP-NDA of the display panel DP may correspond to the non-display region ED-NDA of the electronic device ED described with reference to FIG. 1 and the non-transmission region NTA described with reference to FIG. 2.

The base layer BL may be disposed at the lowermost portion of the display panel DP to provide a base surface for disposing components or layers of the display panel DP. The base layer BL may include a synthetic resin layer. The synthetic resin layer may include a thermosetting resin. In particular, the synthetic resin layer may be a polyimide-based resin layer, and the material is not particularly limited. The synthetic resin layer may include at least one of an acrylic resin, a methacrylic resin, a polyisoprene resin, a vinyl resin, an epoxy resin, a urethane resin, a cellulose resin, a siloxane resin, a polyamide resin, and a perylene resin. In addition, the base layer may include a glass substrate, a metal substrate, or an organic/inorganic composite material substrate.

The base layer BL may be provided in a form in which organic layers and inorganic layers are alternately stacked. For example, the base layer BL may be provided in a structure in which a first organic layer including polyimide, a first inorganic layer disposed on the first organic layer, a second organic layer disposed on the first inorganic layer, and a second inorganic layer disposed on the second organic layer are stacked, and the present disclosure is not limited to any one embodiment.

The circuit element layer DP-CL may include a plurality of insulating layers and a circuit element. The insulating layers may include at least one inorganic layer and at least one organic layer. The circuit element may include signal lines and a driving circuit. The insulating layer and the circuit element may be formed by forming an insulating layer, a semiconductor layer, and a conductive layer through processes, such as a coating process and a deposition process, and then selectively patterning the resulting structure through photolithography and etching processes. Accordingly, a semiconductor pattern, a conductive pattern, and a signal line may be formed in the circuit element layer DP-CL.

A pattern in the same layer as another pattern may be formed through the same process. In this specification, that patterns are formed through the same process may mean that the patterns include the same material and have the same stack structure. As being in a same layer, elements may be formed in a same process and/or include a same material as each other, elements may be respective portions or patterns of a same material layer, elements may be on a same layer by forming an interface with a same underlying or overlying layer, etc., without being limited thereto.

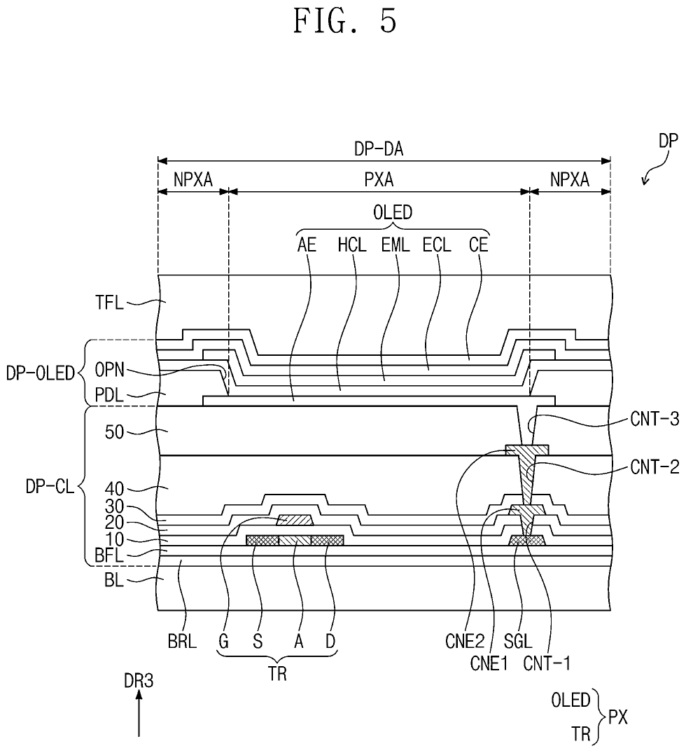

The display element layer DP-OLED may include a pixel defining layer PDL (see FIG. 5) and an organic light emitting element OLED as a light emitting element (see FIG. 5).

The encapsulating layer TFL may be disposed on the display element layer DP-OLED to cover the display element layer DP-OLED. The encapsulating layer TFL may prevent moisture/oxygen from being infiltrated into the display element layer DP-OLED. The encapsulating layer TFL may include a stack structure of an inorganic layer/organic layer/inorganic layer.

The input sensing unit ISU may be disposed on the display panel DP. In this specification, the wording “a component A is directly disposed on a component B” refers to that another component is not intervened between the component A and the component B.

FIG. 4 is a plan view of a display panel DP according to an embodiment of the present disclosure.

Referring to FIG. 4, according to an embodiment, the display panel DP may include pixels PX, a gate driving circuit GDC, signal lines SGL, and pads DP-PD.

The pixels PX may be disposed in the display region DP-DA. Each of the pixels PX may include a light emitting element and a pixel driving circuit which is connected to the light emitting element. According to an embodiment, the light emitting element may be an organic light emitting element.

The gate driving circuit GDC may be disposed in the non-display region DP-NDA of the display panel DP. The gate driving circuit GDC may sequentially output gate signals to gate lines GL. A circuit transistor of the gate driving circuit GDC may be formed through the same process, such as a low temperature polycrystalline silicon (LTPS) process, a low temperature polycrystalline oxide (LTPO) process, or a hybrid oxide and polycrystalline silicon (HOP) process, as a transistor TR of the pixel PX.

However, a driving circuit included in the display panel DP is not limited to the gate driving circuit GDC. For example, the display panel DP may further include another driving circuit to apply a light emitting control signal to the pixels PX. For example, the display panel DP may include a scan driving circuit.

The signal lines SGL may be disposed in the display region DP-DA and may extend from the display region DP-DA to the non-display region DP-NDA. The signal lines SGL may include the gate lines GL, data lines DL, a power line PL, and a control signal line CSL. The gate lines GL may be connected to relevant pixels PX among the pixels PX, respectively, and the data lines DL may be connected to relevant pixels PX among the pixels PX, respectively. The power line PL may be connected to the pixels PX. The control signal line CSL may provide control signals to the scan driving circuit.

Each of the signal lines SGL may include a line part LP. Although not illustrated, the signal lines SGL may further include a pad part. The line part LP may be overlapped with the display region DP-DA and the non-display region DP-NDA. The pad part may be connected to an end portion (e.g., a distal end) of the line part LP.

The pad DP-PD as a pad of the display panel DP may be provided in plural including first pads PD1, second pads PD2, and third pads PD3.

The non-display region DP-NDA may include a first pad region PA1 and a second pad region PA2. The first pad region PA1 may be a region in which the first and second pads PD1 and PD2 are disposed and overlapped with the driving chip DC (see FIG. 2). The second pad region PA2 may be a region in which the third pads PD3 are disposed and overlapped with the circuit board PB.

The first pad region PA1 and the second pad region PA2 may be spaced apart from each other in (or along) the first direction DR1.

The first pad region PA1 may include a first region B1 as a first sub-region in which the first pads PD1 are disposed and a second region B2 as a second sub-region in which the second pads PD2 are disposed.

A region, in which the first and second pads PD1 and PD2 are disposed, together may be defined as the first pad region PA1, and a region, in which the third pads PD3 are disposed, may be defined as the second pad region PA2.

According to an embodiment, the first pads PD1 may be arranged in one row in the first region B1. However, the manner for arranging the first pads PD1 in the first region B1 is not limited thereto. According to an embodiment, the first pads PD1 may be arranged in at least two rows in the first region B1.

Referring to FIG. 4, the second region B2 may be disposed under the first region B1, that is, closer to an end of the display panel DP than the first region B1. The second pads PD2 disposed in the second region B2 may be connected to the third pads PD3 disposed in the second pad region PA2, through connection signal lines S-CL. The first pads PD1 disposed in the first pad region PA1 may not be connected to the second pads PD2 in the first pad region PA1 by a connection line. For example, the first and second pads PD1 and PD2 may be connected to each other via the driving chip DC, without being limited thereto.

The circuit board PB may include substrate bumps PB-BP. The substrate bumps PB-BP as circuit board bumps may be arranged in the second direction DR2. The substrate bumps PB-BP of the circuit board PB may be connected to the display panel DP at the third pads PD3 in the second pad region PA2 while making contact with the third pads PD3. As being in contact, elements may be physically in contact with each other, such as forming an interface therebetween.

FIG. 5 is a cross-sectional view of a display panel DP according to an embodiment of the present disclosure. FIG. 5 illustrates a cross-section corresponding to a light emitting region PXA and a non-light emitting region NPXA which is adjacent to the light emitting region PXA. The definition of the light emitting region PXA and the non-light emitting region NPXA will be described below.

The display panel DP includes the base layer BL, the circuit element layer DP-CL disposed on the base layer BL, the display element layer DP-OLED disposed on the circuit element layer DP-CL, and the encapsulating layer TFL disposed on the display element layer DP-OLED.

Although FIG. 5 illustrates only one transistor TR as an example of the pixel driving circuit for the convenience of explanation, an embodiment of the present disclosure is not limited thereto. For example, the pixel PX may include a plurality of transistors TR.

According to an embodiment, the circuit element layer DP-CL may include a barrier layer BRL, a buffer layer BFL, and a first insulating layer 10 to a fifth insulating layer 50, the transistor TR, a signal line SGL, a first connection electrode CNE1, and a second connection electrode CNE2. However, an embodiment of the present disclosure is not limited thereto. For example, the barrier layer BRL or the buffer layer BFL may be omitted, or any one insulating layer in the range from the first insulating layer 10 to the fifth insulating layer 50 may be omitted, or another insulating layer may be further intervened among the first insulating layer 10 to the fifth insulating layer 50.

The barrier layer BRL is disposed on the base layer BL. The barrier layer BRL prevents foreign substances from being introduced to layers above the barrier layer BRL, from the outside. The barrier layer BRL may include a silicon oxide layer and a silicon nitride layer. The silicon oxide layer may include a plurality of silicon oxide layers and the silicon nitride layer may include a plurality of silicon nitride layers, and the silicon oxide layers and the silicon nitride layers may be alternately stacked.

The buffer layer BFL is disposed on the barrier layer BRL. The buffer layer BFL may improve bonding force between the base layer BL and an overlying layer such as a semiconductor pattern and/or a conductive pattern. The buffer layer BFL may include a silicon oxide layer and a silicon nitride layer. The silicon oxide layer and the silicon nitride layer may be stacked, and a plurality of such layer may be alternately stacked.

A semiconductor pattern is disposed on the buffer layer BFL. The semiconductor pattern may include polysilicon. However, the present disclosure is not limited thereto. For example, the semiconductor pattern may include amorphous silicon or metal oxide.

A portion of the semiconductor pattern is illustrated in FIG. 5, and the semiconductor pattern may be extended along the circuit element layer DP-CL to be further disposed in another region of the display panel DP, when viewed in a plan view. The semiconductor pattern may include a first region and a second region. The first region may be doped with an N-type dopant or a P-type dopant, and may have conductivity (e.g., electrical conductivity) greater than the conductivity of the second region. The first region substantially corresponds to and functions as an electrode element or a conductive signal line. The second region may have a lower doping concentration or may be a non-doped region, and substantially corresponds to an active (or channel) of a transistor TR.

A drain D, an active A, and a source S may be defined or disposed on the buffer layer BFL. The drain D, the active A, and the source S may define the transistor TR together with a gate G to be described later. When the display panel DP further incudes another transistor other than the transistor TR, the another transistor may include a material different from the material of the transistor TR and may be disposed in a layer different from a layer for the transistor TR. The source S, the active A, and the drain D of the transistor TR may be formed from or defined by the semiconductor pattern.

The first insulating layer 10 may be disposed on the buffer layer BFL. The first insulating layer 10 may cover the semiconductor pattern. The first insulating layer 10 may be commonly overlapped with the plurality of pixels PX. The gate G is disposed on the first insulating layer 10. The gate G may be a portion of a metal pattern or a conductive material layer. The gate G may overlap the active A. In the process of doping the semiconductor pattern, the gate G may function as a mask in a process of providing the display panel DP.

The gate G may include titanium (Ti), silver (Ag), an alloy containing silver (Ag), molybdenum (Mo), an alloy containing molybdenum (Mo), aluminum (Al), an alloy containing aluminum (Al), aluminum nitride (AlN), tungsten (W), tungsten nitride (WN), copper (Cu), indium tin oxide (ITO), or indium zinc oxide (IZO), and the present disclosure is not particularly limited thereto.

The second insulating layer 20 covering the gate G may be disposed on the first insulating layer 10. The second insulating layer 20 may be commonly overlapped with the pixels PX. Although not illustrated, an upper electrode overlapped with the gate G may be disposed on the second insulating layer 20. The first connection electrode CNE1 disposed on the second insulating layer 20 may be connected to the signal line SGL through a first contact hole CNT-1 formed (or extended) through the first insulating layer 10 and the second insulating layer 20.

The third insulating layer 30 may be disposed on the second insulating layer 20 to cover an upper electrode and the first connection electrode CNE1.

The first insulating layer 10 to the third insulating layer 30 may include an inorganic layer and/or an organic layer, and may have a single-layer or multilayer structure. One or more among the first to fifth insulating layers 10 to 50 may be referred to as “an insulating layer,” without being limited thereto.

The fourth insulating layer 40 may be disposed on the third insulating layer 30. The fourth insulating layer 40 may be an organic layer. The second connection electrode CNE2 may be disposed on the fourth insulating layer 40. The second connection electrode CNE2 may be connected to the first connection electrode CNE1 through a second contact hole CNT-2 formed through the third insulating layer 30, and the fourth insulating layer 40.

The fifth insulating layer 50 may be disposed on the fourth insulating layer 40 to cover the second connection electrode CNE2. The fifth insulating layer 50 may be an organic layer. A first electrode AE may be disposed on the fifth insulating layer 50. The first electrode AE may be connected to the second connection electrode CNE2 through a third contact hole CNT-3 formed through the fifth insulating layer 50.

The display element layer DP-OLED may include the pixel defining layer PDL and the organic light emitting element OLED. A pixel opening OPN is defined in the pixel defining layer PDL, such as by portions (e.g., material or solid portions) spaced apart from each other. The pixel opening OPN of the pixel defining layer PDL may expose at least a portion of the first electrode AE to outside the pixel defining layer PDL. According to an embodiment, a light emitting region PXA may be defined to correspond to the partial region of the first electrode AE, which is exposed by the pixel opening OPN. For example, a planar area of the light emitting region PXA may correspond to the exposed planar area of the first electrode AE.

A hole control layer HCL may be commonly disposed in the light emitting region PXA and the non-light emitting region NPXA. The hole control layer HCL may include a hole transport layer and may further include a hole injection layer.

A light emitting layer EML is disposed on the hole control layer HCL. The light emitting layer EML may be disposed in a region corresponding to the pixel opening OPN. In other words, the light emitting layer EML may be separately formed as discrete patterns respectively in each of pixels PX. However, the present disclosure is not limited thereto. For example, the light emitting layer EML may be commonly formed in the plurality of pixels PX.

An electron control layer ECL may be disposed on the light emitting layer EML. The electron control layer ECL may include an electron transport layer and may further include an electron injection layer. The hole control layer HCL and the electron control layer ECL may be commonly formed in the plurality of pixels PX through an open mask.

A second electrode CE may be disposed on the electron control layer ECL. The second electrode CE may have an integral-type form, and may be commonly disposed in the plurality of pixels PX.

The encapsulating layer TFL may be disposed on the second electrode CE. The encapsulating layer TFL may include a plurality of thin films. The encapsulating layer TFL may prevent moisture/oxygen from being infiltrated into the display element layer DP-OLED.

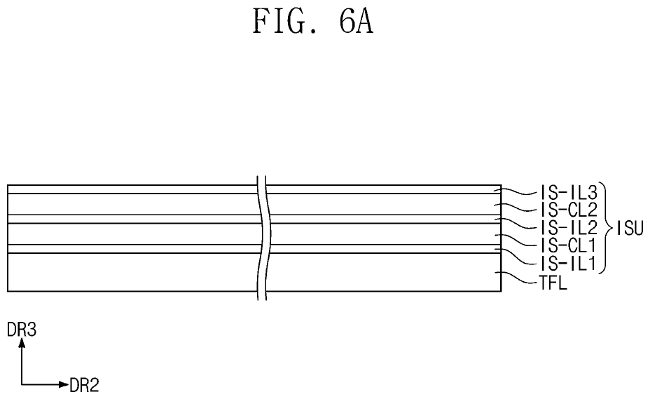

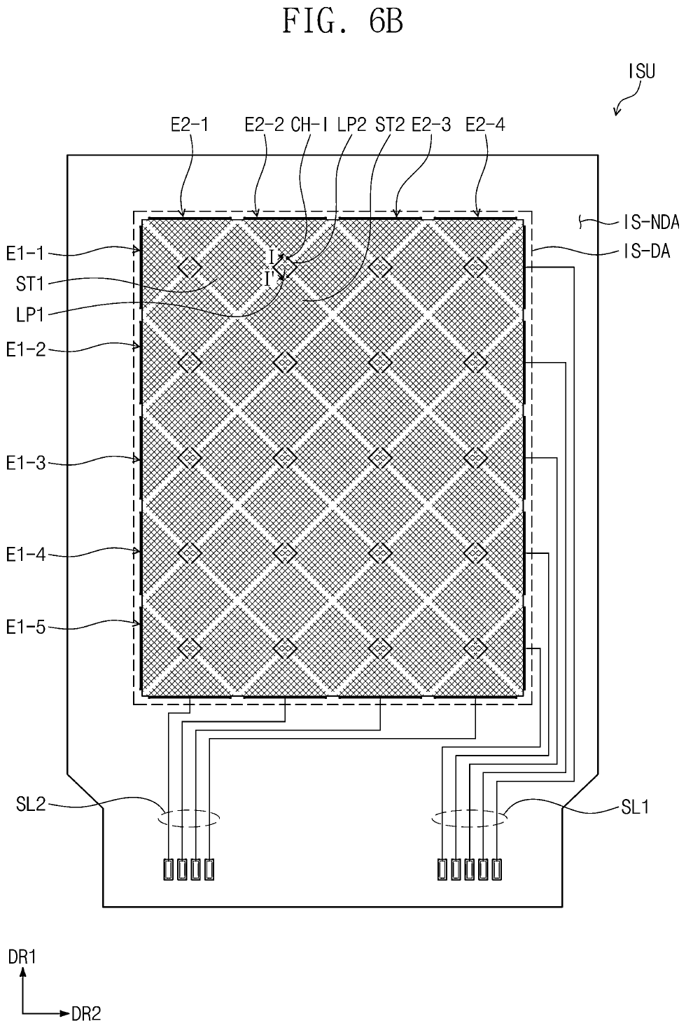

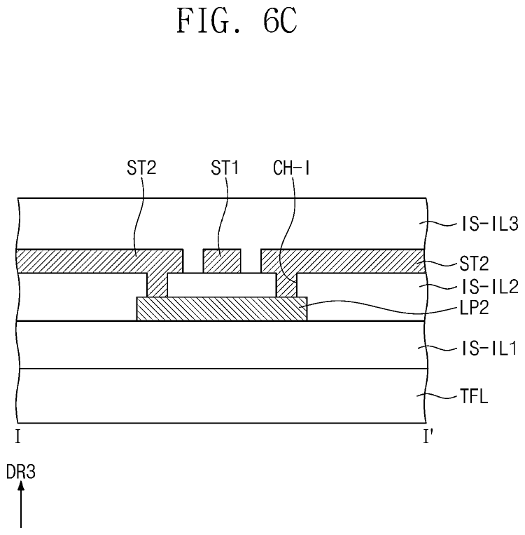

FIG. 6A is a cross-sectional view of an input sensing unit ISU according to an embodiment of the present disclosure.

The input sensing unit ISU may include a first sensing insulating layer IS-IL1, a first sensing conductive layer IS-CL1 disposed on the first sensing insulating layer IS-IL1, a second sensing insulating layer IS-IL2 disposed on the first sensing conductive layer IS-CL1, a second sensing conductive layer IS-CL2 disposed on the second sensing insulating layer IS-IL2, and a third sensing insulating layer IS-IL3 disposed on the second sensing conductive layer IS-CL2. The first sensing insulating layer IS-IL1 may be directly disposed on the encapsulating layer TFL.

However, the present disclosure is not limited thereto, and the first sensing insulating layer IS-IL1 and/or the third sensing insulating layer IS-IL3 may be omitted. When the first sensing insulating layer IS-IL1 is omitted, the first sensing conductive layer IS-CL1 may be directly disposed on the encapsulating layer TFL. The third sensing insulating layer IS-IL3 may be substituted with an adhesive layer or an insulating layer of an anti-reflective member of the input sensing unit ISU.

Each of the first to third sensing insulating layers IS-IL1, IS-IL2, and IS-IL3 may include an inorganic layer or an organic layer. The inorganic layer may include silicon oxide, silicon nitride, or silicon oxy nitride, and the organic layer may include at least one of an acrylic resin, a methacrylic resin, polyisoprene, a vinyl resin, an epoxy resin, a urethane resin, a cellulose resin, a siloxane resin, a polyimide resin, a polyamide resin, and a perylene resin.

According to an embodiment, at least one of the first sensing insulating layer IS-IL1, the second sensing insulating layer IS-IL2, and the third sensing insulating layer IS-IL3 may be an organic layer. For example, the third sensing insulating layer IS-IL3 may include an organic layer.

In FIG. 6A, each of the first sensing conductive layer IS-CL1 and the second sensing conductive layer IS-CL2 is illustrated in the form of one layer (e.g., a monolayer) overlapped with the entire portion of the display panel DP to schematically express a stack structure. However, an embodiment of the present disclosure is not limited thereto, and each of the first sensing conductive layer IS-CL1 and the second sensing conductive layer IS-CL2 may be patterned to include discrete shapes or discrete patterns along the encapsulating layer TFL.

FIG. 6B is a plan view of an input sensing unit ISU according to an embodiment of the present disclosure. FIG. 6C is a cross-sectional view of a portion of a display device DD taken along line I-I′ of FIG. 6B.

Referring to FIG. 6B, the input sensing unit ISU may include a sensing region IS-DA and a non-sensing region IS-NDA which is adjacent to the sensing region IS-DA. The sensing region IS-DA and the non-sensing region IS-NDA may correspond to the display region DP-DA (see FIG. 3) and the non-display region DP-NDA (see FIG. 3), respectively. Referring to FIG. 6B, the input sensing unit ISU may include first electrodes E1-1 to E1-5, second electrodes E2-1 to E2-4, first signal lines SL1, and second signal lines SL2.

The first electrodes E1-1 to E1-5 and the second electrodes E2-1 to E2-4 may be disposed in the sensing region IS-DA. The first electrodes E1-1 to E1-5 and the second electrodes E2-1 to E2-4 may be insulated from each other (e.g., electrically insulated) while crossing each other in a plan view.

The first signal lines SL1 and the second signal lines SL2 may be disposed in the non-sensing region IS-NDA. The first signal lines SL1 may be electrically connected to the first electrodes E1-1 to E1-5, respectively, and the second signal lines SL2 may be electrically connected to the second electrodes E2-1 to E2-4, respectively.

The first electrodes E1-1 to E1-5, the second electrodes E2-1 to E2-4, the first signal lines SL1, and the second signal lines SL2 may be portions of the first sensing conductive layer IS-CL1 or the second sensing conductive layer IS-CL2.

The first electrodes E1-1 to E1-5 and the second electrodes E2-1 to E2-4 may include a plurality of conductive lines crossing each other. A plurality of conductive lines may be spaced apart from each other to define a plurality of openings therebetween, and the first electrodes E1-1 to E1-5 and the second electrodes E2-1 to E2-4 may have a mesh form by the conductive lines and the openings therebetween. Each of the plurality of openings may be defined to correspond to the pixel opening OPN of the pixel defining layer PDL illustrated in FIG. 5.

The first electrodes E1-1 to E1-5 may include sensing parts ST1 and intermediate parts LP1 which extend from the sensing parts ST1 while forming an integral or unitary structure with the sensing parts ST1. In other words, although the sensing parts ST1 and the intermediate parts LP1 connecting to the sensing parts ST1 to each other have an integral-structured pattern formed through the same process as portions of a same material layer, the sensing parts ST1 and the intermediate parts LP1 will be separately described for the convenience of explanation.

The second electrodes E2-1 to E2-4 may include sensing patterns ST2 and bridge patterns LP2 (or connection patterns).

Referring to FIGS. 6B and 6C, two adjacent sensing patterns ST2 may be connected to each other by the bridge pattern LP2, at or through the contact hole CH-I formed through the second sensing insulating layer IS-IL2.

One of the first signal lines SL1 and the second signal lines SL2 transmits a transmit signal for sensing an external input from an external circuit, and another one of the first signal lines SL1 and the second signal lines SL2 transmits a change in capacitance between the first electrodes E1-1 to E1-5 and the second electrodes E2-1 to E2-4 as a receive signal to the external circuit.

The first signal lines SL1 and the second signal lines SL2 may have a multi-layer structure, and the first layer line and the second layer line may be connected to each other through the contact hole CH-I formed through the second sensing insulating layer IS-IL2 (see FIG. 6A).

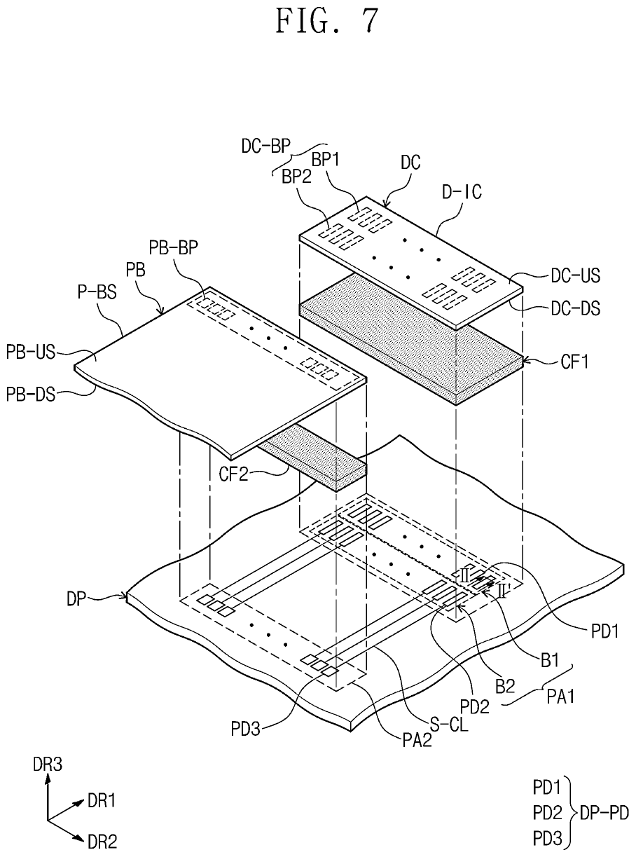

FIG. 7 is an exploded perspective view of pad regions PA1 and PA2 of the display device DD according to an embodiment of the present disclosure. In FIG. 7, the driving chip DC and the circuit board PB are exploded from the display panel DP. Since the arrangement relationship and connection relationship between the first pad region PA1 and the second pad region PA2 have been described above with reference to FIG. 4, the details thereof will be omitted hereinafter.

Referring to FIG. 7, the driving chip DC may be bonded to the display panel DP at the first pad region PA1, through a first adhesive layer CF1. The circuit board PB may be bonded to the display panel DP at the second pad region PA2, through a second adhesive layer CF2.

According to an embodiment, the first adhesive layer CF1 and the second adhesive layer CF2 may include a non-conductive film (NCF), instead of an anisotropic conductive film (ACF). Therefore, the first adhesive layer CF1 and the second adhesive layer CF2 may include a synthetic resin having an adhesive property, and a conductive material or a conductive element such as a conductive ball may not be included in the non-conductive film (NCF).

The driving chip DC may include a driving integrated circuit D-IC and driving bumps DC-BP which are mounted in the driving chip DC.

The driving integrated circuit D-IC may include a top surface DC-US and a bottom surface DC-DS which is opposite to the top surface DC-US. The bottom surface DC-DS of the driving integrated circuit D-IC may be a surface facing the first pad PD1 and the second pad PD2 along the thickness direction.

The driving bumps DC-BP may be disposed on the bottom surface DC-DS of the driving integrated circuit D-IC. The driving bumps DC-BP may include first bumps BP1 electrically connected to the display panel DP at the first pads PD1, respectively, and second bumps BP2 electrically connected to the display panel DP at the second pads PD2, respectively. The first bumps BP1 may be arranged in the second direction DR2, and the second bumps BP2 may be spaced apart away from the first bumps BP1 in the first direction DR1, and may be arranged in the second direction DR2. Although FIG. 7 illustrates that the first bumps BP1 are arranged in one row and the second bumps BP2 are arranged in one row, an embodiment of the present disclosure is not limited thereto. For example, the first bumps BP1 may be arranged in at least two rows and the second bumps BP2 may be arranged in at least two rows.

The driving chip DC may receive first signals through the second pads PD2, at the second bumps BP2. The driving chip DC may provide second signals generated based on the first signals to the first pads PD1, through the first bumps BP1. For example, the driving chip DC may include a data driving circuit, and generate the second signals based on the first signals through the data driving circuit.

The first signal may be an image signal which is a digital signal applied from the outside, and the second signal may be a data signal which is an analog signal. The driving chip DC may generate an analog voltage corresponding to the gray value of the image signal. The data signal may be provided to the pixel PX through a data line DL (see FIG. 4).

Although not illustrated, the first bumps BP1 and the second bumps BP2 may protrude from or be exposed at the bottom surface DC-DS of the driving integrated circuit D-IC and may be exposed to the outside of the driving integrated circuit D-IC. In a method of providing a display device DD, when uncured material for providing the first adhesive layer CF1 is cured, the first pads PD1 and the first bumps BP1 may be fixed in position relative to each other (e.g., in one or all of the first to third directions DR1 to DR3), while making contact with each other, and the second pads PD2 and the second bumps BP2 may be fixed in position relative to each other while making contact with each other.

The circuit board PB may include a base layer P-BS and the substrate bumps PB-BP which are mounted in or on the base layer P-BS. The circuit board PB may include a top surface PB-US and a bottom surface PB-DS which opposes the top surface PB-US, and the bottom surface PB-DS of the circuit board PB may be a surface facing the third pads PD3.

The substrate bumps PB-BP may be disposed on the bottom surface PB-DS of the base layer P-BS. The substrate bumps PB-BP may be electrically connected to the display panel DP at the third pads PD3, respectively. The substrate bumps PB-BP may be arranged in the second direction DR2. Although FIG. 7 illustrates that the substrate bumps PB-BP are arranged in one row, an embodiment of the present disclosure is not limited thereto. For example, the substrate bumps PB-BP may be arranged in at least two rows.

The circuit board PB may provide an image signal, a driving voltage, and other control signals to the driving chip DC.

Although not illustrated, the substrate bumps PB-BP may protrude or be exposed from the bottom surface PB-DS of the base layer P-BS and be exposed to the outside of the circuit board PB. When the second adhesive layer CF2 is cured, the third pads PD3 and the substrate bumps PB-BP may be fixed in position relative to each other (e.g., in one or all of the first to third directions DR1 to DR3), while making contact with each other.

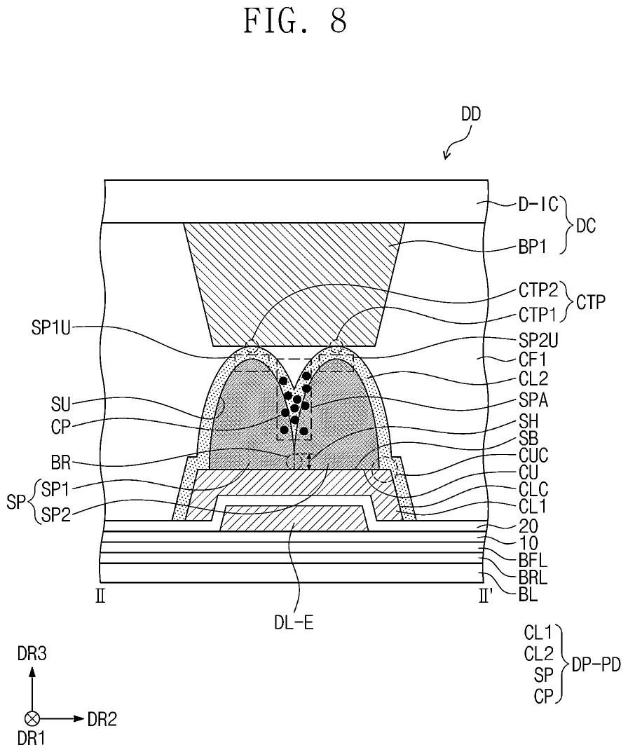

FIG. 8 is a cross-sectional view of a portion of a display device DD taken along line II-II′ of FIG. 7.

The bonding structure between electronic parts, in which the pad DP-PD disposed in the first region B1 (see FIG. 4) is bonded to the first bump BP1, will be described with reference to FIG. 8.

The pad DP-PD illustrated in FIG. 8 may be any one among the first pad PD1 to the third pad PD3 described above with reference to FIGS. 4 and 7. Although FIG. 8 illustrates that an end portion DL-E of the data line DL (see FIG. 4) is the signal line SGL (see FIG. 4), an embodiment of the present disclosure is not limited thereto. The end portion DL-E may be an end portion of another signal line SGL other than the data line DL. The end portion DL-E may correspond to the pad part described above with reference to FIG. 4.

Hereinafter, the bonding structure of the pad DP-PD will be described while focusing on the bonding between the display panel DP at the first pad PD1 (see FIG. 4) overlapped with the end portion DL-E of the data line DL (see FIG. 4), and the first bump BP1 of the driving chip DC. The second pad PD2 and the third pad PD3 may be overlapped with the end portion of the connection signal line S-CL (see FIG. 4) instead of the end portion DL-E of the data line DL. The second pad PD2 may be bonded to the second bump BP2 of the driving chip DC (see FIG. 2), and the third pads PD3 may be bonded to the substrate bump PB-BP of the circuit board PB (refer to FIG. 7).

Referring to FIG. 8, the end portion DL-E may be disposed on the first insulating layer 10. The end portion DL-E may be disposed in the same layer as the gate G (see FIG. 5). The end portion DL-E may be formed through the same process as the gate G. The end portion DL-E may include the same material as the gate G.

However, the position of the end portion DL-E is not limited thereto. For example, the end portion DL-E may be positioned in the same layer as the upper electrode described with reference to FIG. 5, may include the same material as the upper electrode, and may have the same stack structure as the upper electrode. Some of the signal lines SGL (refer to FIG. 4) may be formed through the same process as the gate G (refer to FIG. 5), and others of the signal lines SGL may be formed through the same process as the upper electrode described with reference to FIG. 5.

Referring to FIG. 8, the display device DD may include the base layer BL, the barrier layer BRL, the buffer layer BFL, the first insulating layer 10, the second insulating layer 20, the pad DP-PD, the first adhesive layer CF1, and the driving chip DC in the first region B1.

The barrier layer BRL, the buffer layer BFL, and the first and second insulating layers 10 and 20 illustrated in FIG. 8 may be formed through the same process as the barrier layer BRL, the buffer layer BFL, and the first and second insulating layers 10 and 20 illustrated in FIG. 5. In other words, the stack structure of the base layer BL, the barrier layer BRL, the buffer layer BFL, and the first and second insulating layers 10 and 20 illustrated in FIG. 8 may vary depending on the stack structure of the circuit element layer DP-CL (see FIG. 5).

The pad DP-PD may be disposed on the second insulating layer 20. The pad DP-PD may include a first conductive pattern CL1, an insulating pattern SP, a second conductive pattern CL2, and a conductive member CP.

The first conductive pattern CL1 may be disposed on the second insulating layer 20. Although not illustrated, the first conductive pattern CL1 may contact the end portion DL-E through the contact hole formed through the second insulating layer 20. Accordingly, the first conductive pattern CL1 and the end portion DL-E may be electrically connected to each other.

The insulating pattern SP may be disposed on the first conductive pattern CL1. Referring to FIG. 8, the insulating pattern SP and the first conductive pattern CL1 may make contact with each other. However, an embodiment of the present disclosure is not limited thereto. For example, an insulating layer may be further disposed between the insulating pattern SP and the first conductive pattern CL1. Accordingly, the insulating pattern SP and the first conductive pattern CL1 may not make contact with each other.

The insulating pattern SP may have a continuous integral form. The insulating pattern SP may include a first protrusion SP1 and a second protrusion SP2 which is connected to the first protrusion SP1. A part in which the first protrusion SP1 is connected to the second protrusion SP2 in the insulating pattern SP may be defined as a connection part BR. A boundary between the first and second protrusions SP1 and SP2 or an area at which the first and second protrusions SP1 and SP2 meet each other may define the connection part BR. According to an embodiment, the first and second protrusions SP1 and SP2 may be adjacent to each other in a direction along the first conductive pattern CL1.

When viewed in a cross-sectional view, the insulating pattern SP may have thicknesses at locations along the first conductive pattern CL1. The thickness SH (hereinafter, a “connection part thickness”) of the insulating pattern SP is defined at the connection part BR. The connection part thickness SH may have the value exceeding ‘0’. In other words, the first protrusion SP1 and the second protrusion SP2 may be connected to each other at some thickness of the insulating pattern SP, through the connection part BR. Accordingly, the insulating pattern SP may have a continuous integral form by connection of the first and second protrusions SP1 and SP2 to each other.

The first protrusion SP1 and the second protrusion SP2 may protrude in a direction away from the first insulating layer 10 and the second insulating layer 20. Referring to FIG. 8, the first protrusion SP1 and the second protrusion SP2 may protrude in the third direction DR3.

A portion in the first protrusion SP1, which is defined in a place farthest away from the first and second insulating layers 10 and 20, may be defined as a first insulating layer pattern upper part SP1U. A portion in the second protrusion SP2, which is defined in a place farthest away from the first and second insulating layers 10 and 20, may be defined as a second insulating layer pattern upper part SP2U. The first and second insulating layer pattern upper parts SP1U and SP2U may correspond to the uppermost portions of the first and second protrusions SP1 and SP2 in the third direction DR3, in the insulating pattern SP. The uppermost portions of the first and second protrusions SP1 and SP2 may include a point, an edge or a plane which is furthest from the insulating layer.

The insulating pattern SP has widths at locations along a thickness thereof. The width of each of the protrusions SP1 and SP2 in a direction which the protrusions SP1 and SP2 are arranged, such as, the direction along the first conductive pattern CL1, may decrease as a distance from the first conductive pattern CL1 increases. According to an embodiment, the width of each of the protrusions SP1 and SP2 in the second direction DR2 may be decreased in the third direction DR3.

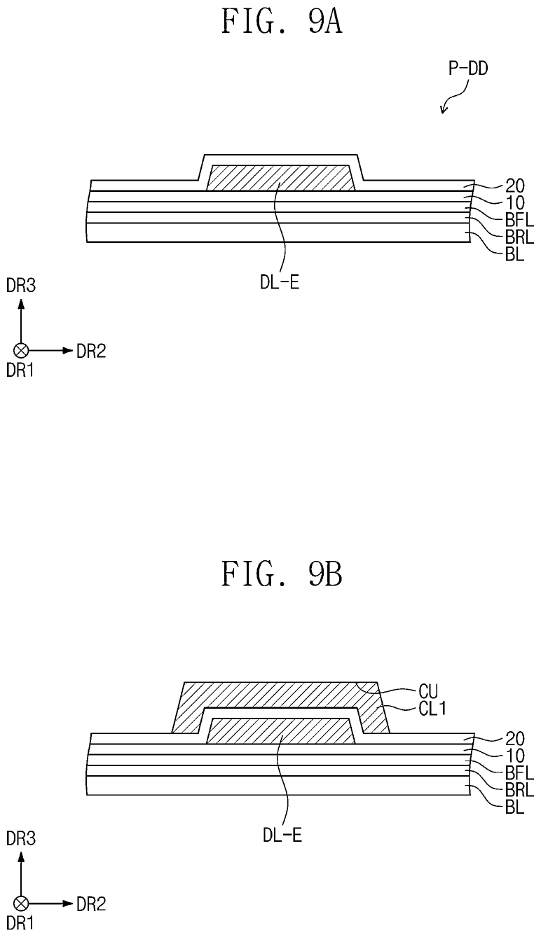

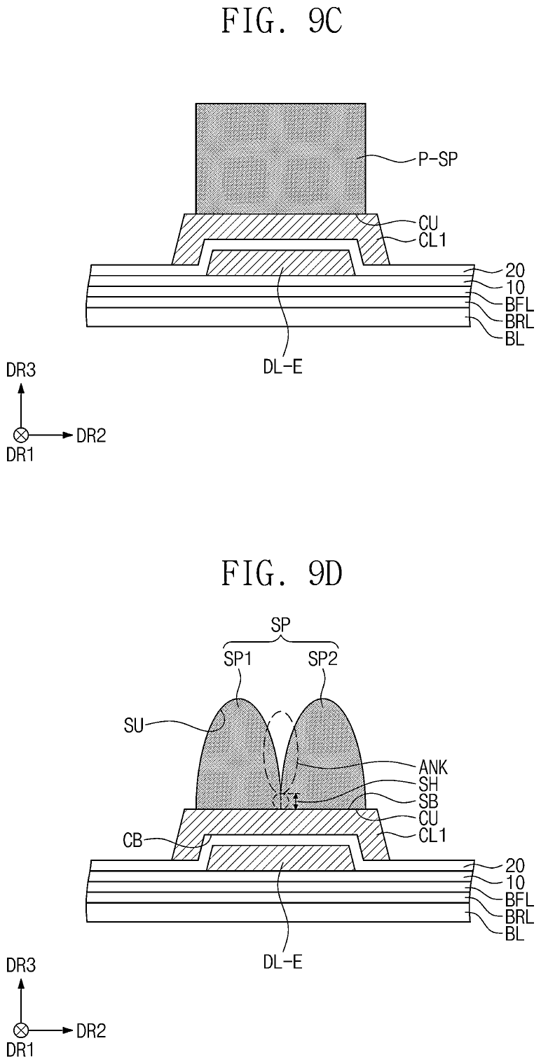

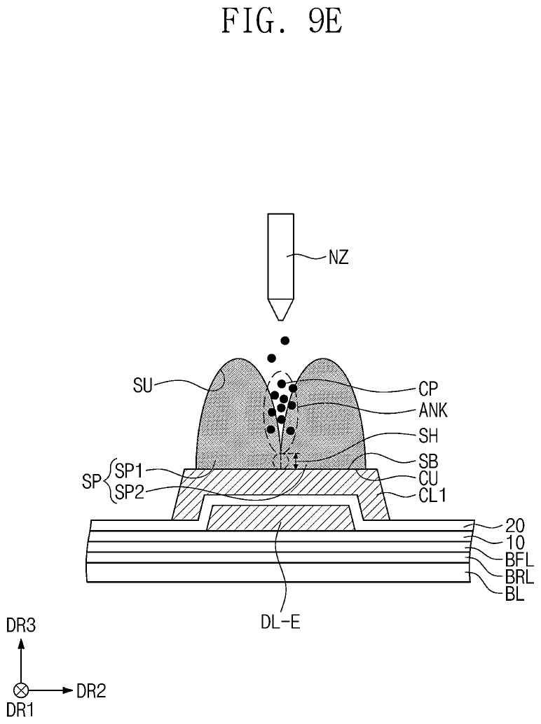

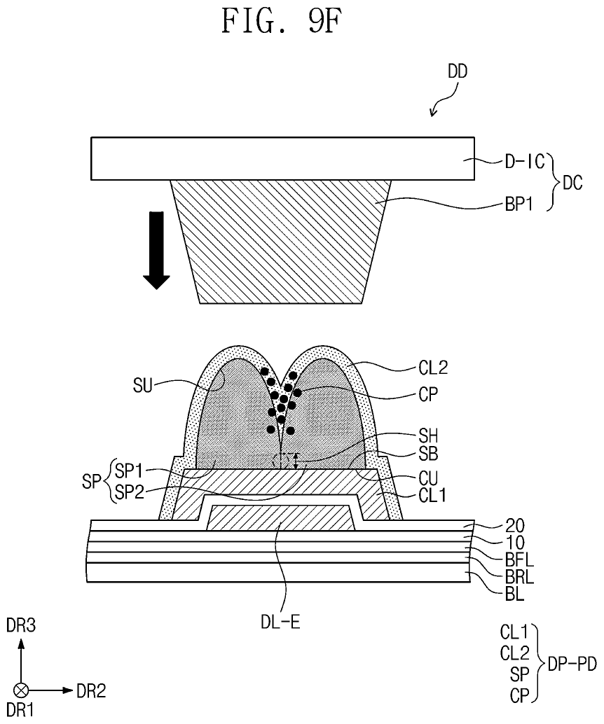

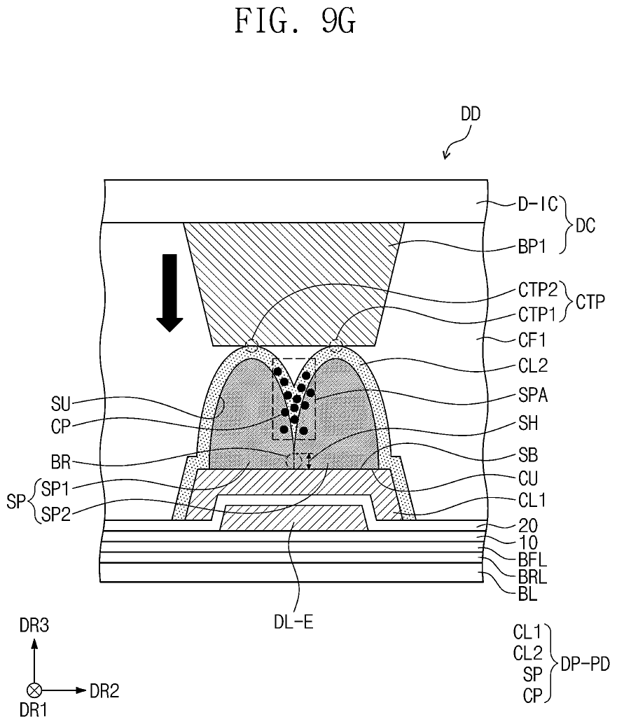

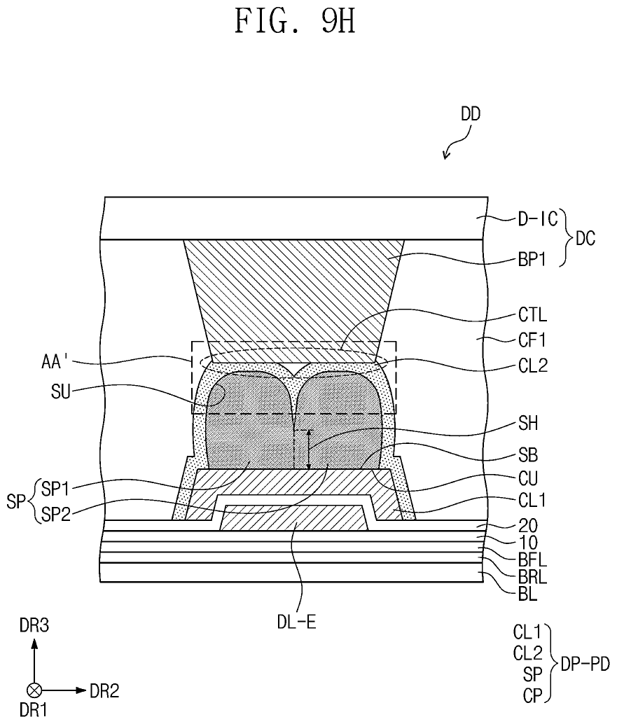

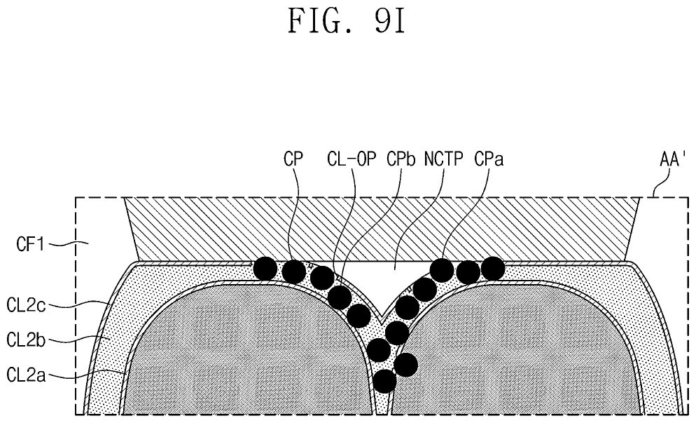

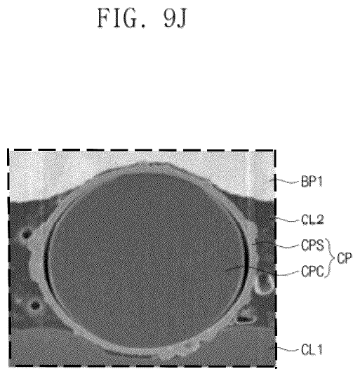

A valley ANK (see FIG. 9D) may be defined between the first protrusion SP1 and the second protrusion SP2, in the insulating pattern SP. The valley ANK may correspond to a part where the insulating pattern SP is recessed in a direction opposite to the direction in which the first protrusion SP1 and the second protrusion SP2 protrude. When viewed in a cross-sectional view, the valley ANK may be defined between the first and second insulating layer pattern upper parts SP1U and SP2U in the second direction DR2, and extend to the connection part BR. The upper parts SP1U and SP2U may include peaks of the respective protrusions, where the valley ANK is defined between the peaks.

The second conductive pattern CL2 may be disposed on the insulating pattern SP. The first conductive pattern CL1 may include a top surface CU which is close to the insulating pattern SP, for example, on which the insulating pattern SP is disposed, a bottom surface CB (see FIG. 9D) opposite to the top surface CU, and a side surface CLC connected to the top surface CU and the bottom surface CB. A bottom surface SB of the insulating pattern SP may be coplanar with the top surface CU of the first conductive pattern CL1. The top surface CU may extend further than the insulating pattern SP to define an exposed portion of the top surface CU. The second conductive pattern CL2 may make contact with a portion CUC of the top surface CU and the side surface CLC, which are exposed from the insulating pattern SP. Accordingly, the second conductive pattern CL2 and the first conductive pattern CL1 may be electrically connected to each other at the exposed portion of the first conductive pattern CL1.

The second conductive pattern CL2 has a multi-layer structure. According to an embodiment, the second conductive pattern CL2 may include a (2-1)-th pattern or pattern layer CL2a, a (2-2)-th pattern or pattern layer CL2b disposed on the (2-1)-th pattern CL2a, and a (2-3)-th pattern or pattern layer CL2c disposed on the (2-2)-th pattern CL2b (see FIG. 9I).

The (2-3)-th pattern CL2c may include a material different from a material of the (2-2)-th pattern CL2b. The (2-3)-th pattern CL2c may include a material having reactivity lower than that of the material of the (2-2)-th pattern CL2b. For example, the (2-3)-th pattern CL2c may include a material having oxygen reactivity lower than that of the material of the (2-2)-th pattern CL2b. The (2-3)-th pattern CL2c may prevent the (2-2)-th pattern CL2b from being exposed to oxygen to prevent the (2-2)-th pattern CL2b from being corroded by oxygen. According to an embodiment, a thickness of the (2-3)-th pattern CL2c may be smaller than a thickness of the (2-2)-th pattern CL2b.

For example, the (2-1)-th pattern CL2a and (2-3)-th pattern CL2c may include titanium (Ti), and the (2-2)-th pattern CL2b may include aluminum (Al). However, the stack structure and the material of the second conductive pattern CL2 are not limited thereto. For example, the second conductive pattern CL2 may include the (2-1)-th pattern CL2a including copper (Cu) and the (2-2)-th pattern CL2b including indium tin oxide (ITO).

Although not illustrated, the first conductive pattern CL1 has the same stack structure as that of the second conductive pattern CL2, and may include the same material as that of the second conductive pattern CL2.

According to an embodiment, the conductive member CP may be interposed between the protrusions SP1 and SP2. The region for the conductive member CP may be defined as a conductive member region SPA. The conductive member region SPA may be interposed between the first and second insulating layer pattern upper parts SP1U and SP2U in the second direction DR2.

The conductive member CP may be randomly arranged. However, the present disclosure is not limited thereto. The conductive members CP may be arranged under a specific rule.

At least a portion of the conductive member CP may extend into a body of the second conductive pattern CL2. The at least a portion of the conductive member CP may extend into a body of the insulating pattern SP. The conductive member CP may make contact with the top surface SU of the insulating pattern SP, and may be disposed on the top surface SU of the insulating pattern SP. The conductive member CP may penetrate a top surface SU of the insulating pattern SP which is opposite to the bottom surface SB thereof. The process of inserting a portion of the conductive member CP into the second conductive pattern CL2 and/or the insulating pattern SP will be described later with reference to FIGS. 9A to 9G.

The first bump BP1 may be disposed on the second conductive pattern CL2. The first bump BP1 and the second conductive pattern CL2 may at least partially make contact with each other. Referring to FIG. 8, as the first bump BP1 and the second conductive pattern CL2 make contact with each other, a contact point CTP may be defined between the first bump BP1 and the second conductive pattern CL2. As the first bump BP1 moves down towards the pad DP-PD in a method of providing the display panel DP, the first bump BP1 may apply pressure to the second conductive pattern CL2 by making contact with the second conductive pattern CL2. The pressure applied by the first bump BP1 to the second conductive pattern CL2 may be transmitted through the contact point CTP.

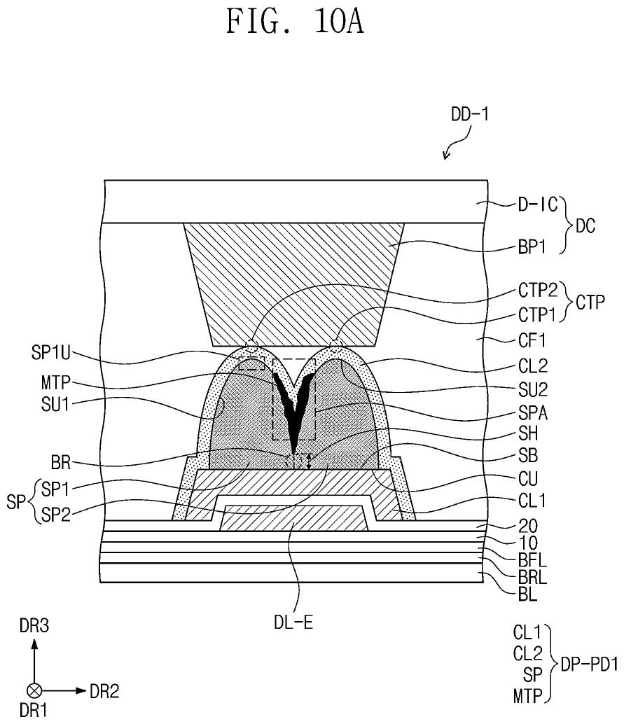

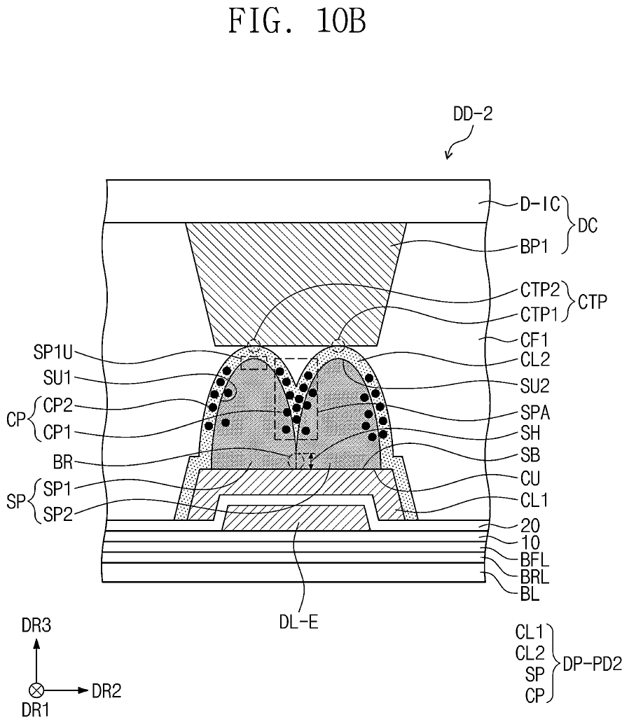

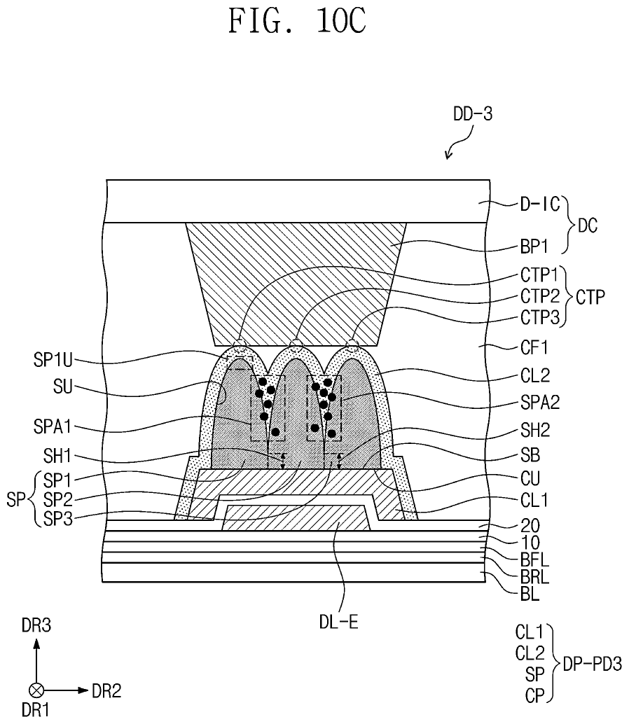

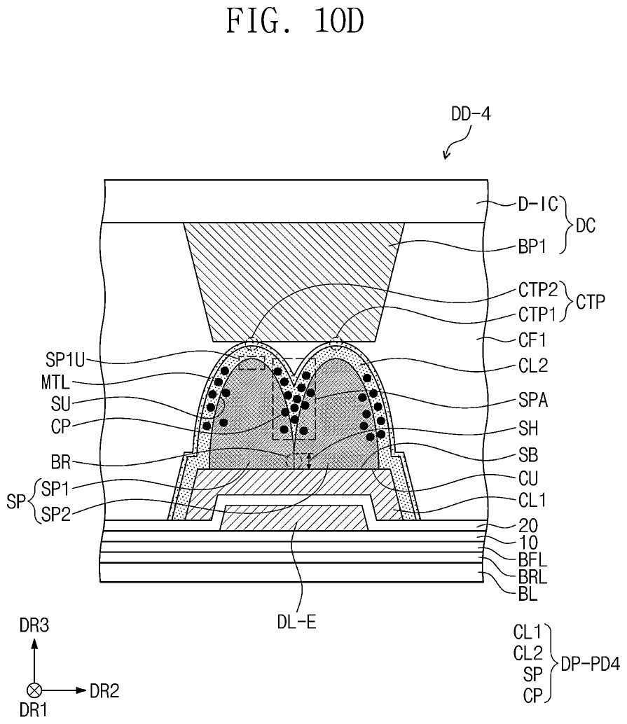

Contact points CTP may include a first contact CTP1, a second contact CTP2, a third contact CTP3 (see FIG. 10C), etc. between the pad DP-PD and a same one bump of the driving chip DC, corresponding to the number of protrusions in the pad DP-PD. The contacts may be defined at a point or discrete area, may be defined along an edge formed by a point extended in a planar direction, etc. without being particularly limited thereto.

The second conductive pattern CL2 and the first conductive pattern CL1 may at least partially make contact with each other. FIG. 8 illustrates that a portion of the top surface CU of the first conductive pattern CL1 and the side surface CLC of the first conductive pattern CL1 are covered by the second conductive pattern CL2. However, an embodiment of the present disclosure is not limited thereto as long as the second conductive pattern CL2 makes contact with the first conductive pattern CL1 to be electrically connected thereto.

According to an embodiment, the conductive member CP may include a spherical shape conductive particle having an uneven outer surface. For example, the conductive member CP may include a metal layer having an uneven pattern along an upper portion of a spherical polymer layer. However, the present disclosure is not limited thereto. The conductive member CP may include a metal paste including conductive particles. According to an embodiment, the conductive member CP may include conductive particles randomly arranged in the second conductive pattern CL2.

According to an embodiment, the insulating pattern SP may include polymer. Accordingly, the insulating pattern SP may have an insulating property. In addition, as the insulating pattern SP has polymer, the insulating pattern SP has an clastic modulus. Accordingly, the insulating pattern SP receives pressure from the outside to be deformed in response to the pressure. Accordingly, the bonding reliability of the pad DP-PD may be increased.

According to an embodiment, as the pad DP-PD includes the conductive member CP between the first protrusion SP1 and the second protrusion SP2, the conductive member CP may be collected in the valley ANK. Accordingly, since the conductive member CP is not interposed between the pad DP-PD and another adjacent pad, an unexpected electrical short circuit between the adjacent pads may be prevented. Accordingly, the reliability for the electrical connection of components within the display device DD may be ensured.

FIGS. 9A to 9H are cross-sectional views sequentially illustrating operations and structure in a method for providing (or manufacturing) a display device DD according to an embodiment of the present disclosure. FIG. 9I is an enlarged view of region AA′ of FIG. 9H.

Referring to FIGS. 9A to 9H, according to an embodiment of the present disclosure, a method for providing (or manufacturing) a display device DD may include providing a preliminary display device P-DD including the base layer BL including the display region DP-DA (see FIG. 3) and the non-display region DP-NDA which is adjacent to the display region DP-DA (see FIG. 3), and the insulating layers 10 and 20 disposed on the base layer BL, providing (or forming) the first conductive pattern CL1 in the non-display region DP-NDA of the base layer BL, forming a preliminary insulating pattern P-SP on the first conductive pattern CL1, forming the insulating pattern SP including the protrusions SP1 and SP2 protruding in a direction away from the insulating layers 10 and 20 by etching the preliminary insulating pattern P-SP, forming a conductive member CP between the protrusions SP1 and SP2, and forming the second conductive pattern CL2 on the insulating pattern SP. In addition, at least a portion of the conductive member CP may be inserted into or extend into the second conductive pattern CL2.

Referring to FIG. 9A, the preliminary display device P-DD may include the base layer BL including the display region DP-DA (see FIG. 3) and the non-display region DP-NDA which is adjacent to the display region DP-DA (see FIG. 3) and the insulating layers 10 and 20 which are disposed on the base layer BL,

The end portion DL-E of the data line DL (see FIG. 4) may be disposed on the first insulating layer 10. The second insulating layer 20 may cover the end portion DL-E of the data line DL.

Thereafter, referring to FIGS. 9B and 9C, the preliminary insulating pattern P-SP may be formed on the top surface CU of the first conductive pattern CL1 after forming the first conductive pattern CL1 in the non-display region DP-NDA of the base layer BL. Accordingly, the top surface CU of the first conductive pattern CL1 may make contact with the bottom surface SB (see FIG. 9D) of the preliminary insulating pattern P-SP. Although the preliminary insulating pattern P-SP may include the same material as the insulating pattern SP (see FIG. 9D), the preliminary insulating pattern P-SP may be an un-patterned member before forming the insulating pattern SP through an etching process

Thereafter, referring to FIG. 9D, the insulating pattern SP including the protrusions SP1 and SP2 protruding in the direction away from the insulating layers 10 and 20 may be formed by patterning the preliminary insulating pattern P-SP (see FIG. 9C), such as by etching. In the etching of the preliminary insulating pattern P-SP, a mask may be overlapped with the preliminary insulating pattern P-SP, and the resulting structure may be etched through a photoresist process.

In performing this process, etching may be performed so as not to completely penetrate a thickness of the preliminary insulating pattern P-SP corresponding to a boundary between the first protrusion SP1 and the second protrusion SP2. In other words, the first protrusion SP1 and the second protrusion SP2 may be connected to each other at a lower thickness portion of the preliminary insulating pattern P-SP, through the connection part BR, and the insulating pattern SP may have a continuous integral form without being disconnected or separated in to discrete portions.

Referring to FIG. 9E, the forming of the conductive member CP between the first protrusion SP1 and the second protrusion SP2 may be performed. The providing of the conductive member CP may include disposing a discharging member NZ above the insulating pattern SP, and discharging material of the conductive member CP from the discharging member NZ to the insulating pattern SP which is partially separated between the first and second protrusions SP1 and SP2.

When the material of the insulating pattern SP is not fully cured, a portion of the conductive member CP discharged from the discharging member NZ may be at least partially inserted or extended into the insulating pattern SP which is uncured.

The conductive member CP discharged from the discharging member NZ may be captured into and collect within the valley ANK of the insulating pattern SP which is defined above the connection part BR. Since the material of the insulating pattern SP which is not fully cured has the conductive members CP provided thereto, the conductive members CP may penetrate the top surface SU of the insulating pattern SP owing to the conductive members CP providing a penetrating force (e.g., by weight of the members, by gravity, etc.) greater than a resisting force of the uncured insulating pattern.

The discharging member NZ is spaced apart from the insulating pattern SP by a specific distance, and the conductive member CP discharged from the discharging member NZ moves down through the distance and is disposed above the insulating pattern SP. Accordingly, the conductive member CP may be randomly arranged without a specific arranging rule owing to the discharging of the conductive member material into the valley ANK. However, an embodiment of the present disclosure is not limited thereto. For example, when a rule for discharging the conductive member CP from the discharging member NZ is made, the conductive members CP may be arranged under the rule.

Referring to the stacked structure having the insulating pattern SP with the conductive member CP between the protrusions SP1 and SP2 (FIG. 9E, once the discharging member NZ is removed), the second conductive pattern CL2 is provided on the insulating pattern SP. At least a portion of the conductive members CP collected within the valley ANK of the insulating pattern SP may be inserted into the second conductive pattern CL2. Here, the lower surface of the second conductive pattern CL2 may be penetrated by the conductive members CP, such as owing solely to the low resistance force of the second conductive pattern CL2 against the conductive members CP (e.g., by weight of the second conductive pattern CL2, by gravity, by shape of the conductive members CP, etc.).

Thereafter, referring to FIGS. 9F and 9G, after the forming of the second conductive pattern CL2, the disposing of the first bump BP1 on the second conductive pattern CL2 and the applying pressure to the second conductive pattern CL2 by moving the first bump BP1 toward of the second conductive pattern CL2 may be performed.

However, an embodiment of the present disclosure is not limited thereto. For example, the pad DP-PD may be moved toward the first bump BP1 to apply pressure to the second conductive pattern CL2.

In an embodiment, an adhesive material layer may be applied on the structure in FIG. 9F. Pressing of the driving chip DC to the display panel DP at the pad DP-PD may displace the adhesive material layer and bring the first bump BP1 into contact with the second conductive pattern CL2, as shown in FIG. 9G, without being limited thereto. In an embodiment, the pressing of the driving chip DC to the display panel DP to bring the first bump BP1 into contact with the second conductive pattern CL2, as shown in FIG. 9G may occur first, then the adhesive material layer may be provided around the contacting elements.

Referring to FIG. 9G, contact points CTP may be formed between the pad DP-PD and a same one bump of the driving chip DC, corresponding to the number of protrusions in the pad DP-PD. As an initial contact, the contact points CTP may provide a minimum planar area of contact between the pad DP-PD and the driving chip DC.

Referring to FIG. 9H, as the first bump BP1 applies pressure to the second conductive pattern CL2 more, a planar area of the contact points CTP increase to provide a contact surface CTL between the first bump BP1 and the second conductive pattern CL2.

Since the insulating pattern SP including polymer has elasticity, the insulating pattern SP may be deformed by pressure applied by the first bump BP1. However, the deformation of the pad DP-PD illustrated in FIG. 9H is provided for the illustrative purpose, but an embodiment of the present disclosure is not limited thereto. Here, the second conductive pattern CL2 is deformed together with the insulating pattern SP to essentially planarize an upper portion of the second conductive pattern CL2.

Referring to FIG. 9I, in the pressing of the second conductive pattern CL2, the portion of the conductive member CP inserted into the second conductive pattern CL2 may be at least partially exposed from the second conductive pattern CL2 which is deformed. In other words, the conductive member CP may be exposed from the (2-3)-th pattern CL2c at a through part CL-OP of the (2-3)-th pattern CL2c, after forming the through part CL-OP in the (2-3)-th pattern CL2c by applying the pressure to the conductive member CP. Here, the through part CL-OP may be provided by a penetrating force of the conductive member CP through the thickness of the (2-3)-th pattern CL2c.

An exposed portion of the conductive member CP which penetrates further than an outer surface of the (2-3)-th pattern CL2c may make contact with both the first bump BP1 and the second conductive pattern CL2. Accordingly, the conductive member CP may transmit an electrical signal applied to the first bump BP1, to the second conductive pattern CL2. In other words, the electrical signal may be sequentially transmitted from the first bump BP1, to the conductive member CP, and to the second conductive pattern CL2.

When the first bump BP1 applies pressure to the second conductive pattern CL2, the first bump BP1 may not make contact with the entire outer surface of the second conductive pattern CL2 at an upper portion thereof. In other words, a non-contact space NCTP may be formed as a gap between the first bump BP1 and the second conductive pattern CL2.

However, referring to FIG. 9I, a first conductive member CPa may protrude from the second conductive pattern CL2. An exposed portion of the first conductive member CPa protruding from the second conductive pattern CL2 may make contact with the first bump BP1. In contrast, a second conductive particle CPb does not penetrate an outer surface of the second conductive pattern CL2. Accordingly, the first conductive member CPa may simultaneously make contact with the first bump BP1 and the second conductive pattern CL2. The second conductive pattern CL2 may be electrically connected to the first bump BP1. In other words, according to the present disclosure, as the pad DP-PD includes the first conductive member CPa, the reliability for the electrical connection may be ensured.

In addition, when the conductivity of the (2-2)-th pattern CL2b is higher than that of the (2-3)-th pattern CL2c, the first conductive member CPa may ensure the electrical connection between the (2-2)-th pattern CL2b and the first bump BP1. For example, when the (2-3)-th pattern CL2c includes titanium (Ti), and the (2-2)-th pattern CL2b may include aluminum (Al), the conductivity of the (2-2)-th pattern CL2b may be higher than the conductivity of the (2-3)-th pattern CL2c. The first conductive member CPa may electrically connect the (2-2)-th pattern CL2b to the first bump BP1 by making contact with the first bump BP1, as the through part CL-OP is formed in the (2-3)-th pattern CL2c. Accordingly, according to the present disclosure, as the pad DP-PD includes the first conductive member CPa, among the conductive members CP, the reliability for the electrical connection may be ensured.

FIG. 9J is a cross-sectional view of a conductive member CP according to an embodiment of the present disclosure.

According to an embodiment, the conductive members CP may include spherical conductive particles having an uneven outer surface.

Each of the conductive particle may have a core part CPC and a coating layer CPS surrounding the core part CPC. The core part CPC may have a spherical shape, and the coating layer CPS as an outer layer may have an uneven surface. The bonding force may be maintained between the first bump BP1 (see FIG. 9J) and the second conductive pattern CL2 due to the uneven shape of the coating layer CPS which defines the outer surface of the conductive member CP. Accordingly, the reliability for the electrical connection between the first bump BP1 and the second conductive pattern CL2 may be increased.

The core part CPC may include a polymer resin. The coating layer CPS may include a conductive material. For example, the coating layer CPS may include metal particles including at least one of silver (Ag), copper (Cu), bismuth (Bi), zinc (Zn), indium (In), tin (Sn), nickel (Ni), cobalt (Co), chromium (Cr), and iron (Fe). Accordingly, the conductive members CP may have conductivity.

FIG. 10A is a cross-sectional view of a first region of a portion of a display device DD-1 according to an embodiment of the present disclosure. The same/similar reference numerals will be assigned to the same/similar components as/to components described with reference to FIGS. 7 and 8, and FIGS. 9A to 9J, and the redundant repeat will be omitted. In addition, the following description will be made while focusing on the difference from the same/similar components as/to components described with reference to FIGS. 7 and 8, and FIGS. 9A to 9J.

The bonding structure, in which a pad DP-PD1 disposed in the first region B1 (see FIG. 4) is bonded to the first bump BP1, will be described with reference to FIG. 10A.

Referring to FIG. 10A, a display device DD-1 may include the base layer BL, the barrier layer BRL, the buffer layer BFL, the first insulating layer 10, the second insulating layer 20, the pad DP-PD1, the first adhesive layer CF1, and the driving chip DC in the first region B1.

The pad DP-PD1 may be disposed on the second insulating layer 20. The pad DP-PD1 may include the first conductive pattern CL1, the insulating pattern SP, the second conductive pattern CL2, and a conductive member MTP.

The conductive member MTP may include a metal paste as a single body of conductive material. The metal paste may include a conductive particle. The conductive particle may include metal. For example, the conductive particle may include a silver particle.

Referring to FIG. 10A, at least a portion of the metal paste may be inserted (or extended) into the second conductive pattern CL2. In addition, the metal paste may penetrate the first outer surface SU1 and/or the second outer surface SU2 of the respective first protrusion SP1 and the second protrusion SP2. the at least a portion of the metal paste may be inserted into the first conductive pattern CL1.

According to an embodiment, as the conductive member MTP includes the metal paste in a single body, the reliability for the electrical connection may be ensured by multiple points of conductive contact similar to those provided by the discrete conductive members CP.

FIG. 10B is a cross-sectional view of a first region of a portion of a display device DD-2 according to an embodiment of the present disclosure. The same/similar reference numerals will be assigned to the same/similar components as/to components described with reference to FIGS. 7 and 8, and FIGS. 9A to 9J, and the redundant repeat will be omitted. In addition, the following description will be made while focusing on the difference from the same/similar components as/to components described with reference to FIGS. 7 and 8, and FIGS. 9A to 9J.

The bonding structure, in which a pad DP-PD2 disposed in the first region B1 (see FIG. 4) is bonded to the first bump BP1, will be described with reference to FIG. 10B.

Referring to FIG. 10B, a display device DD-2 may include the base layer BL, the barrier layer BRL, the buffer layer BFL, the first insulating layer 10, the second insulating layer 20, the pad DP-PD2, the first adhesive layer CF1, and the driving chip DC in the first region B1.

The pad DP-PD2 may be disposed on the second insulating layer 20. The pad DP-PD2 may include the first conductive pattern CL1, the insulating pattern SP, the second conductive pattern CL2, and the conductive member CP provided in plural.

The insulating pattern SP may include the first protrusion SP1 and the second protrusion SP2. The first protrusion SP1 and the second protrusion SP2 may respectively include the first outer surface SU1 and the second outer surface SU2. According to an embodiment, each of the first outer surface SU1 and the second outer surface SU2 may include a first side surface facing an adjacent protrusion when viewed in a cross sectional view and a second side surface facing the first side surface.

The conductive members CP may be respectively disposed on opposing sides of an outer surface of the insulating pattern SP. Among the conductive members CP, an entirety of each individual conductive member CP may be adjacent to the outer surfaces SU1 and SU2 without penetrating a respective outer surface.

The conductive members CP may include a first conductive member CP1 provided in plural, entirely on a first side of the outer surfaces SU1 and SU2, that is, within the body of the insulating pattern SP, and a second conductive member CP2 provided in plural, entirely on a second side of the outer surfaces SU1 and SU2, that is, outside of the body of the insulating pattern SP. According to an embodiment, the conductive member CP may be interposed between the first side surfaces of the protrusions SP1 and SP2, and the pad DP-PD2 may further include an additional conductive member disposed on at least one of the second side surfaces of the protrusions SP1 and SP2.

FIG. 10C is a cross-sectional view of a first region of a portion of a display device DD-3 according to an embodiment of the present disclosure. The same/similar reference numerals will be assigned to the same/similar components as/to components described with reference to FIGS. 7 and 8, and FIGS. 9A to 9J, and the redundant repeat will be omitted. In addition, the following description will be made while focusing on the difference from the same/similar components as/to components described with reference to FIGS. 7 and 8, and FIGS. 9A to 9J.

The bonding structure, in which a pad DP-PD3 disposed in the first region B1 (see FIG. 4) is bonded to the first bump BP1, will be described with reference to FIG. 10C.

Referring to FIG. 10C, a display device DD-3 may include the base layer BL, the barrier layer BRL, the buffer layer BFL, the first insulating layer 10, the second insulating layer 20, the pad DP-PD3, the first adhesive layer CF1, and the driving chip DC in the first region B1.

The pad DP-PD3 may be disposed on the second insulating layer 20. The pad DP-PD3 may include the first conductive pattern CL1, the insulating pattern SP, the second conductive pattern CL2, and the conductive member CP.

The insulating pattern SP may include a plurality of protrusions SP1, SP2, and SP3. Referring to FIG. 10C, the protrusions SP1, SP2, and SP3 may include the first protrusion SP1, the second protrusion SP2 connected to the first protrusion SP1, and the third protrusion SP3 connected to the second protrusion SP2 and spaced apart from the first protrusion SP1 while interposing the second protrusion SP2 between the first protrusion SP1 and the third protrusion SP3. According to an embodiment, the protrusions SP1, SP2 and SP3 may define a single body of the insulating pattern SP, and may be adjacent to each other in the direction along the first conductive pattern CL1 and connected to each other.

The insulating pattern SP may include a valley ANK between the first protrusion SP1 and the second protrusion SP2, and a valley ANK between the second protrusion SP2 and the third protrusion SP3. Accordingly, a portion of the conductive member CP may be interposed between the first protrusion SP1 and the second protrusion SP2, and a remaining portion of the conductive member CP may be interposed between the second protrusion SP2 and the third protrusion SP3. A first conductive member region SPA1 may be interposed between the insulating layer pattern upper parts of the first and second protrusions SP1 and SP2, in the second direction DR2. A second conductive member region SPA2 may be interposed between the insulating layer pattern upper parts of the second and third protrusions SP2 and SP3, in the second direction DR2.

When viewed in a cross-sectional view, the insulating pattern SP may have thicknesses at locations along the first conductive pattern CL1. The first connection part thickness SH1 and the second connection part thickness SH2 are defined at respective connection parts BR. The connection part thicknesses may have the value exceeding ‘0’. In other words, the first protrusion SP1, the second protrusion SP2 and the third protrusion SP3 may be connected to each other at some thickness of the insulating pattern SP, through the connection parts BR. Accordingly, the insulating pattern SP may form a single body by connection of the first to third protrusions SP1, SP3 and SP3 to each other.

FIG. 10D is a cross-sectional view of a first region of a portion of a display device DD-4 according to an embodiment of the present disclosure. The same/similar reference numerals will be assigned to the same/similar components as/to components described with reference to FIGS. 7 and 8, and FIGS. 9A to 9J, and the redundant repeat will be omitted. In addition, the following description will be made while focusing on the difference from the same/similar components as/to components described with reference to FIGS. 7 and 8, and FIGS. 9A to 9J.

The bonding structure, in which a pad DP-PD4 disposed in the first region B1 (see FIG. 4) is bonded to the first bump BP1, will be described with reference to FIG. 10D.

Referring to FIG. 10D, a display device DD-4 may include the base layer BL (see FIG. 4), the barrier layer BRL, the buffer layer BFL, the first insulating layer 10, the second insulating layer 20, the pad DP-PD4, the first adhesive layer CF1, and the driving chip DC in the first region B1.

The pad DP-PD4 may be disposed on the second insulating layer 20. The pad DP-PD4 may include the first conductive pattern CL1, the insulating pattern SP, the second conductive pattern CL2, the conductive member CP, and a metal layer MTL.

The metal layer MTL may be disposed on the second conductive pattern CL2. The metal layer MTL may cover the second conductive pattern CL2.

The metal layer MTL may be formed through the same process as the first sensing conductive layer IS-CL1. In other words, the metal layer MTL may include the same material as the first sensing conductive layer IS-CL1, and may have the same stack structure as the first sensing conductive layer IS-CL1.

The metal layer MTL may make contact with the first bump BP1. Accordingly, the metal layer MTL may transmit an electrical signal applied to the first bump BP1 to the conductive member CP or the second conductive pattern CL2. The electrical signal transmitted from the metal layer MTL to the conductive member CP may be transmitted to the second conductive pattern CL2. In other words, the electrical signal may be sequentially transmitted to the first bump BP1, the metal layer MTL, the conductive member CP, and the second conductive pattern CL2, or may be sequentially transmitted to the first bump BP1, the metal layer MTL, and the second conductive pattern CL2. The electrical signal transmitted to the second conductive pattern CL2 may be sequentially transmitted to the first conductive pattern CL1, and the end portion DL-E of the data line DL (see FIG. 4).

According to an embodiment of the present disclosure, the display device DD-4 may be manufactured by performing the step of forming the metal layer MTL on the second conductive pattern CL2, after the step of forming the second conductive pattern CL2 described with reference to FIG. 9F, and the redundant repeat will be omitted.

According to an embodiment of the present disclosure, as the pad included in the display device includes the insulating pattern including the protrusion, the reliability for the bonding between the pad and the bump may be improved.

In an embodiment, for example, a display device includes a base layer including a display region in which a light emitting element and a signal line are disposed, and a non-display region which is adjacent to the display region and includes a pad connected to the signal line. The pad includes a first conductive pattern at which the pad is connected to the signal line, an insulating pattern which is on the first conductive pattern and defines protrusions adjacent to each other in a direction along the first conductive pattern, a second conductive pattern on the insulating pattern and electrically connected to the first conductive pattern, and a conductive member between the protrusions and in the second conductive pattern.

Within the insulating pattern, the protrusions may define a single body of the insulating pattern including a first protrusion and a second protrusion which are adjacent to each other in the direction along the first conductive pattern and connected to each other, and a valley may be defined between the first protrusion and the second protrusion.

Each of the protrusions may have a width in the direction along the first conductive pattern, and the widths may decrease in a direction away from the first conductive pattern.

The first conductive pattern may include a top surface which is close to the insulating pattern and extends further than the insulating pattern to define an exposed portion of the top surface, a bottom surface opposite to the top surface and a side surface connecting the top surface to the bottom surface. The second conductive pattern is electrically connected to the first conductive pattern at the exposed portion of the top surface.

The conductive member may further include a first conductive member which is entirely in the second conductive pattern and outside of the insulating pattern and a second conductive member which is entirely inside the insulating pattern.

In an embodiment, for example, a method for providing a display device includes providing a preliminary display device including a base layer including a display region in which a light emitting element and a signal line are disposed, and a non-display region which is adjacent to the display region and includes a pad region, and in the pad region providing a first conductive pattern of a pad, providing a preliminary insulating pattern on the first conductive pattern, providing an insulating pattern of the pad including protrusions adjacent to each other in a direction along the first conductive pattern, by etching the preliminary insulating pattern, providing a conductive member of the pad, between the protrusions, and providing a second conductive pattern of the pad, on the insulating pattern which has the protrusions. The conductive member is in the second conductive pattern.

In the method, the providing of the conductive member may include providing the conductive member from a discharging member and directly between the protrusions of the insulating pattern.

The method may further include providing a bump facing the pad, and pressing the second conductive pattern having the conductive member therein, to the bump, to expose the conductive member outside of the second conductive pattern.

Although embodiments of the present disclosure has been described for illustrative purposes, those skilled in the art will appreciate that various modifications, and substitutions are possible, without departing from the scope and spirit of the present disclosure as disclosed in the accompanying claims. Accordingly, the technical scope of the present disclosure is not limited to the detailed description of this specification, but should be defined by the claims.

While the present disclosure has been described with reference to embodiments thereof, it will be apparent to those of ordinary skill in the art that various changes and modifications may be made thereto without departing from the spirit and scope of the present disclosure as set forth in the claims.

What is claimed is:

1. A display device comprising:
a display panel including:
a display region in which a light emitting element and a signal line are disposed, and
a non-display region which is adjacent to the display region and in which a pad connected to the signal line is disposed, the pad comprising:
a first conductive pattern at which the pad is connected to the signal line;
an insulating pattern which is on the first conductive pattern and defines protrusions adjacent to each other in a direction along the first conductive pattern;
a second conductive pattern on the insulating pattern and electrically connected to the first conductive pattern; and
a conductive member between the protrusions and at least partially in the second conductive pattern.

2. The display device of claim 1, wherein within the insulating pattern:
the protrusions define a single body of the insulating pattern including a first protrusion and a second protrusion which are adjacent to each other in the direction along the first conductive pattern and connected to each other; and
a valley is defined between the first protrusion and the second protrusion.

3. The display device of claim 1, wherein
each of the protrusions has a width in the direction along the first conductive pattern; and
the widths decrease in a direction away from the first conductive pattern.

4. The display device of claim 1, wherein the conductive member extends from the second conductive pattern and into the insulating pattern.

5. The display device of claim 1, wherein the second conductive pattern includes:
a (2-1)-th pattern layer including titanium;
a (2-2)-th pattern layer including aluminum on the (2-1)-th pattern layer including titanium; and
a (2-3)-th pattern layer including titanium on the (2-2)-th pattern layer including aluminum.

6. The display device of claim 5, wherein
a thickness of the (2-3)-th pattern layer is smaller than a thickness of the (2-2)-th pattern layer, and
the conductive member extends through the (2-3)-th pattern layer and is exposed outside of the pad.

7. The display device of claim 1, wherein the second conductive pattern includes:
a (2-1)-th pattern layer including copper; and
a (2-2)-th pattern layer including indium tin oxide on the (2-1)-th pattern layer including copper.

8. The display device of claim 1, wherein
the first conductive pattern includes:
a top surface which is closest to the insulating pattern and extends further than the insulating pattern to define an exposed portion of the top surface;
a bottom surface opposite to the top surface; and
a side surface connecting the top surface to the bottom surface, and
the second conductive pattern is electrically connected to the first conductive pattern at the exposed portion of the top surface.

9. The display device of claim 8, further comprising:
a driving chip on the non-display region and including a bump overlapped with the pad,
wherein the bump of the driving chip and the second conductive pattern of the pad contact each other.

10. The display device of claim 9, wherein the conductive member extends outside of the second conductive pattern and contacts the bump.

11. The display device of claim 1, wherein the conductive member includes:
conductive particles randomly arranged in the second conductive pattern.

12. The display device of claim 11, wherein the conductive particles include spherical conductive particles having an uneven outer surface.

13. The display device of claim 1, wherein the conductive member includes a metal body extending from the second conductive pattern and into the insulating pattern.

14. The display device of claim 1, wherein the insulating pattern includes a polymer.

15. The display device of claim 1, wherein each of the protrusions includes:
a first side surface facing an adjacent protrusion when viewed in a cross sectional view; and
a second side surface facing the first side surface,
wherein the conductive member is interposed between the first side surfaces, and
wherein the pad further includes:
an additional conductive member disposed on at least one of the second side surfaces.

16. The display device of claim 1, wherein within the insulating pattern:
the protrusions define a single body of the insulating pattern including a first protrusion, a second protrusion and a third protrusion which are adjacent to each other in the direction along the first conductive pattern and connected to each other; and
a valley is defined between the first protrusion and the second protrusion and between the second protrusion and the third protrusion.

17. The display device of claim 1, wherein the pad further includes a metal layer covering the second conductive pattern.

18. A method for providing a display device, the method comprising:
providing a preliminary display device including a base layer including:
a display region and a non-display region adjacent to the display region and insulating layers disposed on the base layer;
forming a first conductive pattern in the non-display region of the base layer;
forming a preliminary insulating pattern on the first conductive pattern;
forming an insulating pattern including protrusions protruding in a direction away from the first conductive pattern by etching the preliminary insulating pattern;
forming a conductive member between the protrusions; and
forming a second conductive pattern on the insulating pattern,
wherein at least a portion of the conductive member may be inserted into the second conductive pattern.

19. The method of claim 18, wherein the providing of the conductive member includes providing the conductive member from a discharging member and directly between the protrusions of the insulating pattern.

20. The method of claim 18, further comprising:
providing a bump facing the pad; and
pressing the second conductive pattern having the conductive member therein, to the bump, to expose the conductive member outside of the second conductive pattern.

21. The method of claim 18, further comprising:
providing a metal layer on the second conductive pattern after providing of the second conductive pattern.
